(19) United States
(12) Patent Application Publication
(10) Pub. No.: US 2018/0329558 A1
(43) Pub. Date: Nov. 15, 2018

(54) ELECTRONIC DEVICE HAVING PRESSURE SENSOR

(71) Applicant: MODA-INNOCHIPS CO., LTD., Ansan-Si, Gyeonggi-Do (KR)

(72) Inventors: In Kil PARK, Seongnam-Si, Gyeonggi-Do (KR); Jun Ho JUNG, Siheung-Si, Gyeonggi-Do (KR)

(21) Appl. No.: 15/774,260

(22) PCT Filed: Nov. 4, 2016
(86) PCT No.: PCT/KR2016/012629

§ 371 Date: May 7, 2018

(30) Foreign Application Priority Data
Nov. 6, 2015 (KR) 10-2015-0156156
Oct. 31, 2016 (KR) 10-2016-0143268

(51) Int. Cl. G06F 3/041; H01L 41/047; G02F 1/1335; G02F 1/1343; G02F 1/1333

(52) U.S. Cl. CPC G06F 3/0414; G06F 3/0412; H01L 41/047; G02F 1/13338; G02F 1/133553; G02F 1/1343; G02F 1/133602

(57) ABSTRACT

The present disclosure proposes an electronic device including: a window; a display part configured to display an image through the window; and a pressure sensor configured to detect a position and a pressure of a touch input applied through the window, wherein the pressure sensor includes: first and second electrode layers provided spaced apart from each other; and a piezoelectric layer provided between the first and second electrode layers, and the piezoelectric layer includes a plurality of cutaway portions formed with predetermined widths and depths.

### TECHNICAL FIELD

The present disclosure relates to an electronic device, and more particularly, to an electronic device provided with a pressure sensor capable of preventing a touch input error while performing a predetermined function by a user's touch.

### BACKGROUND ART

In order to operate electronic devices such as various mobile communication terminals, various types of input devices are being used. For example, input devices such as buttons, keys, and a touch screen panel are being used. A touch screen panel, that is, a touch sensor detects the touch of a human body and enables an electronic device to be easily and simply operated only by a light touch. Therefore, the use thereof is being increased. That is, the touch sensor has a technical means which detects and recognizes touch or non-touch of a human body (finger) or a pen using the detection of human body current due to the touch or a change in pressure, temperature, or the like. Such a touch input device is not only used for mobile communication terminals but also for the operation of home appliances, industrial devices, automobiles, and the like.

Touch sensors used for electronic devices, such as mobile communication terminals, may each be provided between a protective window and a liquid crystal display panel displaying an image. Accordingly, characters, symbols, and the like are displayed from a liquid crystal display panel through the window, and when a user touches the corresponding portion, the touch sensor determines the position thereof and performs a specific processing according to a control flow.

However, in the electronic device using only a touch sensor, a touch error of a user occurs, and an undesired operation may be performed. Thus, in order to reduce the touch error, the need for a method of detecting a touch input with a touch position has been emerging.

### RELATED ART DOCUMENTS

Korean Patent Registration No. 10-1094165

Korean Patent Application Laid-open Publication No. 2014-0023440

### PRESENT DISCLOSURE

### Technical Problem

The present disclosure provides an electronic device provided with a pressure sensor capable of preventing a touch input error.

The present disclosure provides an electronic device provided with a pressure sensor capable of improving the brittleness.

### Technical Solution

In accordance with an aspect of the present invention, an electronic device includes: a window; a display part configured to display an image through the window; and a pressure sensor configured to detect a position and a pressure of a touch input applied through the window, wherein the pressure sensor includes: first and second electrode layers provided spaced apart from each other; and a piezoelectric layer provided between the first and second electrode layers, and the piezoelectric layer includes a plurality of plate-like piezoelectric bodies provided in a polymer.

The piezoelectric bodies are arranged in plurality in one direction and another direction crossing each other in a horizontal direction and are arranged in plurality in a vertical direction.

The piezoelectric bodies are provided to have densities of 30% to 99%.

The piezoelectric bodies include single crystals.

The piezoelectric bodies each include: a seed composition formed of: an orientation raw material composition composed of a piezoelectric material having a perovskite crystalline structure; and an oxide which is distributed in the orientation raw material composition and has a general formula ABO₃ (A is a bivalent metal element, and B is a tetravalent metal element).

In accordance with another aspect of the present invention, an electronic device includes: a window; a display part configured to display an image through the window; and a pressure sensor configured to detect a position and a pressure of a touch input applied through the window, wherein the pressure sensor includes: first and second electrode layers provided spaced apart from each other; and a piezoelectric layer provided between the first and second electrode layers, and the piezoelectric layer includes a plurality of cutaway portions formed with predetermined widths and depths.

The cutaway portions are formed to depths of 50% to 100% of a thickness of the piezoelectric layer.

The pressure sensor further includes an elastic layer provided inside the cutaway portions.

The piezoelectric bodies include single crystals.

The piezoelectric layer includes: a seed composition formed of: an orientation raw material composition composed of a piezoelectric material having a perovskite crystalline structure; and an oxide which is distributed in the orientation raw material composition and has a general formula ABO₃ (A is a bivalent metal element, and B is a tetravalent metal element).

The pressure sensor includes at least any one of at least one first pressure sensor provided under the display part; and at least one second pressure sensor provided under the window.

The electronic device further includes a touch sensor provided between the window and the display part.

The electronic device further includes an insulating layer provided on at least one among places on the first electrode layer, between the first and second electrode layers, and under the second electrode layer.

The electronic device further includes first and second connection patterns respectively provided on the first and second electrode layers and connected to each other.

### Advantageous Effects

An electronic device in accordance with an exemplary embodiment may include a window, a display part, and a pressure sensor, and at least one or more pressure sensors may be provided in at least one place under the display part and under the window. In addition, the pressure sensor may have a piezoelectric layer between first and second electrode layers spaced apart from each other, and the piezoelectric layer may be provided with a plurality of plate-like single-crystal piezoelectric bodies. Since the plate-like piezoelectric bodies are used, the pressure sensor may have piezoelectric characteristics which are better than that employing typical piezoelectric powder. Thus, a minute pressure may also be easily sensed, and thus the sensing efficiency may be improved.

In addition, in the pressure sensor in accordance with an exemplary embodiment, the piezoelectric layer may have a cutaway portion for each cell unit, and an elastic layer may further be formed in the cutaway portions. The plurality of cutaway portions are formed in the piezoelectric layer, and thus, the pressure sensor may have a flexible characteristic.

Meanwhile, the electronic device in accordance with an exemplary embodiment further includes a touch sensor, and may more precisely detect the position and the pressure by the cooperation of the touch sensor and the pressure sensor. That is, the touch sensor and the pressure sensor simultaneously detect coordinates in the horizontal direction (that is, X- and Y-directions), and the pressure sensor detects the pressure in the vertical direction (that is, a Z-direction), and thus, the touch position may be more precisely detected.

### BRIEF DESCRIPTION OF THE DRAWINGS

FIG. 1 is a cross-sectional view of a pressure sensor in accordance with a first exemplary embodiment;

FIGS. 2 and 3 are schematic plan views of first and second electrode layers of a pressure sensor in accordance with exemplary embodiments;

FIG. 4 is a cross-sectional view of a pressure sensor in accordance with a second exemplary embodiment;

FIGS. 5 and 6 are planar and cross-sectional photographs of a pressure sensor in accordance with a second exemplary embodiment;

FIG. 7 is a cross-sectional view of a pressure sensor in accordance with a third exemplary embodiment;

FIG. 8 is a cross-sectional view of a pressure sensor in accordance with a fourth exemplary embodiment;

FIGS. 9 and 10 are schematic plan views of first and second electrode layers of a pressure sensor in accordance with another exemplary embodiments;

FIGS. 11 and 12 are a front perspective view and a rear perspective view which are provided with a pressure sensor in accordance with a first exemplary embodiment;

FIG. 13 is a partial cross-sectional view taken along line A-A′ of FIG. 11;

FIG. 14 is a cross-sectional view of an electronic device in accordance with a second exemplary embodiment;

FIG. 15 is a schematic planar view illustrating a disposition form of a pressure sensor of an electronic device in accordance with a second exemplary embodiment;

FIG. 16 is a cross-sectional view of an electronic device provided with a pressure sensor in accordance with a third exemplary embodiment;

FIG. 17 is a schematic planar view illustrating a disposition form of a pressure sensor of an electronic device in accordance with a fourth exemplary embodiment;

FIGS. 18 to 21 are control configuration diagrams for pressure sensors in accordance with exemplary embodiments;

FIG. 22 is a block diagram for describing a data processing method of a pressure sensor in accordance with another exemplary embodiment;

FIG. 23 is a configuration diagram of a fingerprint recognition sensor employing a pressure sensor in accordance with exemplary embodiments, and

FIG. 24 is a cross-sectional view of a pressure sensor in accordance with another exemplary embodiment.

### MODE FOR CARRYING OUT THE INVENTION

Hereinafter, exemplary embodiments of the present invention will be described in detail with reference to the accompanying drawings. The present invention may, however, be embodied in different forms and should not be construed as limited to the embodiments set forth herein. Rather, these embodiments are provided so that this invention will be thorough and complete, and will fully convey the scope of the present invention to those skilled in the art.

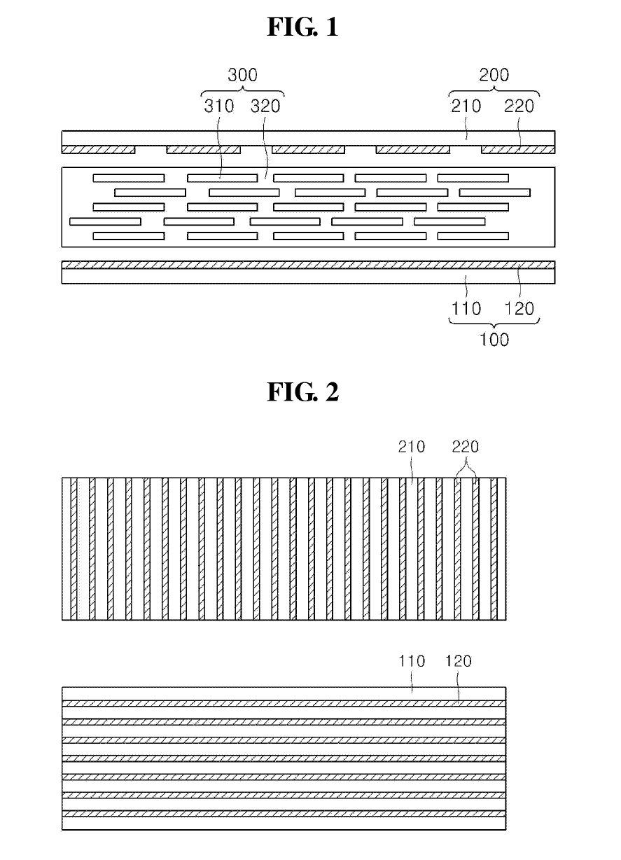

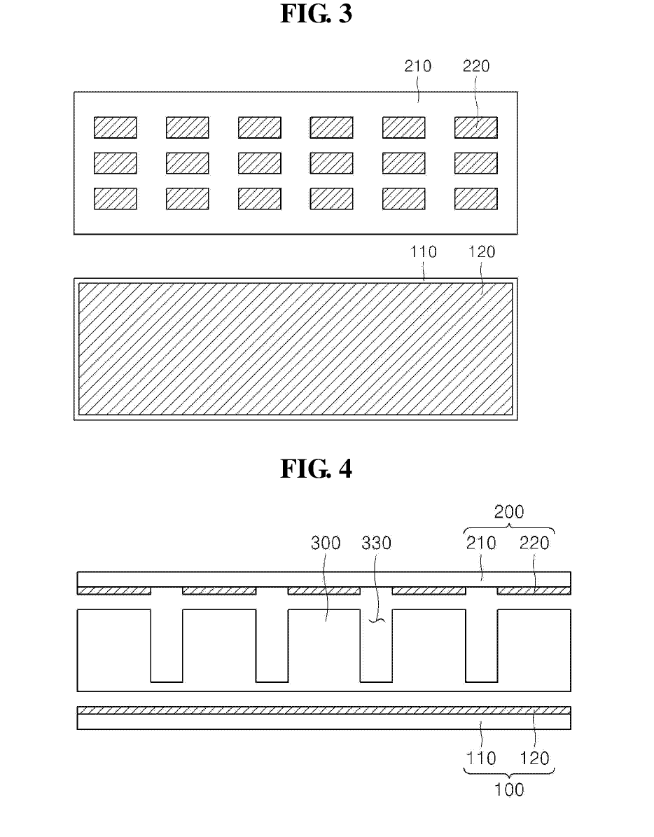

FIG. 1 is a cross-sectional view of a pressure sensor in accordance with a first exemplary embodiment, and FIGS. 2 and 3 are schematic views of first and second electrode layers of a pressure sensor.

Referring to FIG. 1, a pressure sensor in accordance with an exemplary embodiment includes: first and second electrode layers 100 and 200 which are spaced apart from each other; and a piezoelectric layer 300 provided between the first and second electrode layers 100 and 200. Here, the piezoelectric layer 300 may be provided with a plate-like piezoelectric body 310 having a predetermined thickness.

1. Electrode Layer

The first and second electrode layers 100 and 200 are spaced apart from each other in the thickness direction (that is, the vertical direction) and the piezoelectric layer 300 is provided therebetween. The first and second electrode layers 100 and 200 may include: first and second support layers 110 and 210; and first and second electrodes 120 and 220 which are respectively formed on the first and second support layers 110 and 210. That is, the first and second support layers 110 and 210 are formed to be spaced a predetermined distance apart from each other, and the first and second electrodes 120 and 220 are respectively formed on the surfaces of the support layers in the direction facing each other. Here, the first and second electrodes 120 and 220 may be formed in directions facing each other, or may also be formed not facing each other. That is, the first and second electrodes 120 and 220 may be formed to face the piezoelectric layer 300, also be formed such that any one thereof faces the piezoelectric layer 300 and the other does not dace the piezoelectric layer 300, or may both be formed not to face the piezoelectric layer. At this point, the first and second electrodes 120 and 220 may be formed to be in contact with or also to be not in contact with the piezoelectric layer 300. For example, the pressure sensor in accordance with an exemplary embodiment may be implemented by the first support layer 110, the first electrode 120, the piezoelectric layer 300, the second electrode 220, and the second support layer 210 being stacked in the thickness direction from the bottom side. Here, the first and second support layers 110 and 210 support the first and second electrodes 120 and 220 so that the first and second electrodes 120 and 220 are respectively formed on one surface of the first and second support layers 110 and 210. To this end, the first and second support layers 110 and 210 may be provided in a plate shape having a predetermined thickness. In addition, the first and second support layers 110 and 210 may also be provided in a film shape so as to have flexibility. Such first and second support layers 110 and 210 may be formed by using a liquid polymer, such as silicone, urethane, and polyurethane, and may be formed of by using a prepolymer formed by using a liquid photocurable monomer, an oligomer, a photoinitiater, and additives. In addition, optionally, the first and second support layers 110 and 210 may be transparent or opaque. Meanwhile, a plurality of pores (not shown) may be provided in at least one of the first and second support layers 110 and 210. For example, the second support layer 210, the shape of which may be deformed by being bent downward due to a touch or press of an object, may include a plurality of pores. The pores may have sizes of 1 μm to 500 μm and be formed in a porosity of 10% to 95%. The plurality of pores are formed in the second support layer 210, and thus, the elastic force and restoring force of the second support layer 210 may be improved. At this point, when the porosity is 10% or less, the improvement of the elastic force and the restoring force may be insignificant, and when the porosity is greater than 95%, the shape of the second support layer 210 may not be maintained. Also, preferably, the support layers 110 and 220 having the plurality of pores do not have pores formed in the surface thereof. That is, when pores are formed in one surface on which the electrodes 120 and 220 are formed, the electrodes 120 and 220 may be disconnected or the thickness of the electrodes may increase. Therefore, preferably, pores are not formed in the one surface on which the electrodes 120 and 220 are formed.

Meanwhile, the first and second electrodes 120 and 220 may be formed of a transparent conductive material such as an indium tin oxide (ITO) and an antimony tin oxide (ATO). However, besides such materials, the first and second electrodes 120 and 220 may also be formed of another transparent conductive material, and also be formed of an opaque conductive material such as silver (Ag), platinum (Pt) and copper (Cu). Also, the first and second electrodes 120 and 220 may be formed in directions crossing each other. For example, the first electrode 120 may be formed in one direction so as to have a predetermined width, and further formed at intervals in other direction. The second electrode 220 may be formed in another direction perpendicular to the one direction so as to have a predetermined width, and further formed at intervals in the one direction perpendicular to another direction. That is, as illustrated in FIG. 2, the first and second electrodes 120 and 220 may be formed in directions perpendicular to each other. For example, the first electrode 120 may be formed to have a predetermined width in the horizontal direction and further formed in plurality in the vertical direction to be arranged at intervals, and the second electrode 220 may be formed to have predetermined widths in the vertical direction and further formed in plurality in the horizontal direction to be arranged at intervals. Here, the widths of the first and second electrodes 120 and 220 may be equal to or larger than the respective intervals therebetween. Of course, the widths of the first and second electrodes 120 and 220 may also be smaller than the intervals therebetween, but preferably, the widths are larger than the intervals. For example, the ratio of the width to the interval in each of the first and second electrodes 120 and 220 may be 10:1 to 0.5:1. That is, when the interval is 1, the width may be 10 to 0.5. Also, the first and second electrodes 120 and 220 may be formed in various shapes besides such a shape. For example, as illustrated in FIG. 3, any one of the first and second electrode 120 and 220 may entirely be formed on a support layer, and the other may also be formed in plurality in approximately rectangular patterns each having a predetermined width and a predetermined interval in one direction and another direction. That is, a plurality of first electrodes 120 may be formed in approximately rectangular patterns, and the second electrode 220 may entirely be formed on the second support layer 210. Of course, aside from rectangles, various patterns such as circles and polygons may be used. In addition, any one of the first and second electrodes 120 and 220 may entirely be formed on a support layer, and the other may also be formed in a lattice shape which extends in one direction and another direction. Meanwhile, the first and second electrodes 120 and 220 may be formed in a thickness such as 0.1 μm to 500 μm, and the first and second electrodes 120 and 220 may be provided at intervals such as 1 μm to 10,000 μm. Here, the first and second electrodes 120 and 220 may be in contact with the piezoelectric layer 300. Of course, the first and second electrodes 120 and 220 maintain the states of being spaced a predetermined distance apart from the piezoelectric layer 300, and when a predetermined pressure, such as user's touch input, is applied, at least any one of the first and second electrodes 120 and 220 may locally be in contact with the piezoelectric layer 300. At this point, the piezoelectric layer 300 may also be compressed to a predetermined depth.

Meanwhile, a plurality of holes (not shown) may be formed in at least any one of the first and second electrode layers 100 and 200. For example, as illustrated in FIG. 3, a plurality of holes may be formed in the first electrode layer 100. That is, the plurality of holes may be formed in the electrode layer used as a ground electrode. Of course, besides the first electrode layer 100, the holes may also be formed in the second electrode layer 200 used as a signal electrode and may also be formed in both the first and second electrode layers 100 and 200. In addition, the holes may also be formed such that at least any one of the first and second electrodes 120 and 220 is removed and the first and second electrode layers 110 and 210 are exposed, and also be formed such that not only the first and second electrodes 120 and 220, but also the first and second support layers 110 and 210 are removed. That is, the holes may also be formed such that the electrodes 120 and 220 are removed and the support layers 110 and 210 are thereby exposed, or also be formed so as to pass through the support layers 110 and 210 from the electrodes 120 and 220. Also, the holes may be formed in a region in which the electrodes 120 and 220 overlap. For example, as illustrated in FIG. 3, the plurality of holes may be formed in the first electrode 120 in the region overlapping the second electrode 220. Here, a single hole may also be formed in the region overlapping the second electrode 220, and two or more holes may also be formed. Of course, as illustrated in FIG. 2, also in the case in which the first and second electrodes 120 and 220 are formed in one direction and another direction perpendicular to the one direction, the holes may be formed in a region at which the first and second electrodes 120 and 220 cross each other. Due to the formation of a hole, the piezoelectric layer 300 may be more easily compressed. Such a hole may be formed in a diameter such as 0.05 mm to 10 mm. When the diameter of a hole is less than 0.05 mm, the compression effect of the piezoelectric layer 300 may decrease, and when the diameter is greater than 10 mm, the restoring force of the piezoelectric layer 300 may decreased. However, the hole size may be variously changed according to the size of a pressure sensor or an input device.

2. Piezoelectric Layer

The piezoelectric layer 300 is provided in a predetermined thickness between the first and second electrode layers 100 and 200, and may be provided in a thickness such as 10 μm to 1000 μm. That is, the piezoelectric layer 300 may be provided in various thicknesses according to the size of an electronic device in which a pressure sensor is adopted. The piezoelectric layer 300 may be formed by using a piezoelectric body 310, which has an approximately rectangular plate shape with a predetermined thickness, and a polymer 320. That is, a plurality of plate-like piezoelectric bodies 310 are provided in the polymer 320, whereby the piezoelectric layer 300 may be formed. Here, the piezoelectric body 310 may be formed by using a piezoelectric material based on PZT (Pb, Zr, Ti), NKN (Na, K, Nb), and BNT (Bi, Na, Ti). Of course, the piezoelectric body 310 may be formed of various piezoelectric materials, and may include: barium titanate, lead titanate, lead zirconate titanate, potassium niobate, lithium niobate, lithium tantalate, sodium tungstate, zinc oxide, potassium sodium niobate, bismuth ferrite, sodium niobate, bismuth titanate, or the like. However, the piezoelectric body 310 may be formed of a fluoride polymer or a copolymer thereof. The predetermined plate-like piezoelectric body 310 may be formed in an approximately rectangular plate shape which has predetermined lengths in one direction and another direction perpendicular to the one direction, and has a predetermined thickness. For example, the piezoelectric body 310 may be formed in a size of 3 μm to 5000 μm. Such a piezoelectric body 310 may be arranged in plurality in one direction and another direction. That is, the plurality of piezoelectric bodies may be arranged in the thickness direction (that is, in the vertical direction) between the first and second electrode layers 100 and 200 and a planar direction (that is, in the horizontal direction) perpendicular to the thickness direction. The piezoelectric bodies 310 may be arranged in a two or more layered structure, such as a five layered structure, in the thickness direction, but the number of layers is not limited. In order to form the piezoelectric bodies 310 in a plurality of layers in the polymer 320, various methods may be used. For example, a piezoelectric body layer with a predetermined thickness may be formed on a polymer layer with a predetermined thickness, and the piezoelectric body layer is stacked in plurality, whereby the piezoelectric layer 300 may be formed. That is, the piezoelectric body layer is formed by disposing plate-like piezoelectric plates on a polymer layer which has a smaller thickness than the piezoelectric layer 300, and the piezoelectric layer 300 may be formed by stacking the plurality of piezoelectric body layers. However, the piezoelectric layer 300, in which the piezoelectric bodies 310 are formed in the polymer 320, may be formed through various methods. Meanwhile, preferably, the piezoelectric bodies 310 have the same size and are spaced the same distance apart from each other. However, the piezoelectric bodies 310 may also be provided in at least two or more sizes and two or more intervals. At this point, the piezoelectric bodies 310 may be formed with a density of 30% to 99%, and preferably provided in the same density in all regions. That is, the piezoelectric bodies 310 may be provided in a content of 30% to 99% with respect the piezoelectric layer containing the polymer. However, the piezoelectric bodies 310 may be provided such that at least one region thereof has a density of 60% or more. For example, when at least one region of the piezoelectric bodies 310 has a density of 65% and at least another region has a density of 90%, a higher power may be generated in the region with the greater density. However, when the piezoelectric bodies have a density of 60% or more, a control unit may sufficiently sense the voltage generated in the piezoelectric layer 300. In addition, the piezoelectric bodies 310 in accordance with an exemplary embodiment have a superior piezoelectric characteristic because being formed in a single crystal form. That is, compared to a case of using typical piezoelectric powder, the plate-like piezoelectric bodies 310 are used, so that a superior piezoelectric characteristic may be obtained, and a pressure may thereby be detected even by a minute touch, and thus, an error in a touch input may be prevented. Meanwhile, the polymer 320 may include, but not limited to, at least one or more selected from the group consisting of epoxy, polyimide and liquid crystalline polymer (LCP). In addition, the polymer 320 may be formed of a thermoplastic resin. The thermoplastic resin may include, for example, one or more elected from the group consisting of novolac epoxy resin, phenoxy-type epoxy resin, BPA-type epoxy resin, BPF-type epoxy resin, hydrogenated BPA epoxy resin, dimer acid modified epoxy resin, urethane modified epoxy resin, rubber modified epoxy resin and DCPD-type epoxy resin. In addition, the polymer 320 may be formed of a material which can be compressed and restored. For example, the polymer 320 may be formed of a material, which can be compressed and restored, among the above materials. Of course, instead of the polymer 320 formed of the above materials, the piezoelectric bodies 310 may be mixed by using a material which can be compressed and restored. For example, silicon, rubber, gel, phorone, urethane, or the like may be used.

Meanwhile, the piezoelectric layer 300 may further contain a material for shielding and absorbing an electromagnetic wave. That is, the piezoelectric layer 320 may further contain a material for shielding and absorbing an electromagnetic wave. At least one or more materials having at least one or more sizes may be used for such a material for shielding and absorbing an electromagnetic wave. That is, the same kind of materials having a plurality of sizes may be used, or two or more different kinds of materials having a plurality of sizes may be used as the material for shielding and absorbing an electromagnetic wave. As such, the material for shielding and absorbing an electromagnetic wave is further contained in the piezoelectric layer 300, whereby the electromagnetic wave may be shielded or absorbed. The material for shielding and absorbing an electromagnetic wave may include ferrite, alumina, or the like, and may be contained in an amount of 0.1 wt % to 50 wt % in the piezoelectric layer 300. That is, based on 100 wt % of the materials constituting the piezoelectric layer 300, 0.01 wt % to 50 wt % of the material for shielding and absorbing an electromagnetic wave may be contained. When the content of the material for shielding and absorbing an electromagnetic wave is 1 wt % or less, the electromagnetic wave shielding and absorbing characteristic may be low, and when exceeding 50 wt %, the piezoelectric characteristic of the piezoelectric layer 300 may be decreased.

3. Another Example of Piezoelectric Body

Meanwhile, the piezoelectric body 310 may be formed by using a piezoelectric ceramic sintered body which is formed by sintering a piezoelectric ceramic composition including a seed composition formed of: an orientation raw material composition composed of a piezoelectric material having a perovskite crystalline structure; and an oxide which is distributed in the orientation raw material composition and has a general formula of ABO₃ (A is a bivalent metal element, and B is a tetravalent metal element). Here, the orientation raw material composition may be formed by using a composition, in which a material having a crystalline structure different from the perovskite crystalline structure forms a solid solution. For example, a PZT-based material, in which PbTiO₃ (PT) having a tetragonal structure and PbZrO₃ (PZ) having a rhombohedral structure form a solid solution, may be used. In addition, in the orientation raw material composition, the characteristics of the PZT-based material may be improved by using a composition in which at least one of Pb(Ni,Nb)O₃ (PNN), Pb(Zn,Nb)O₃ (PZN) and Pb(Mn,Nb)O₃ (PMN) is solid-solutioned as a relaxor in the PZT-based material. For example, the orientation raw material composition may be formed by solid-solutioning, as a relaxor, a PZNN-based material having a high piezoelectric characteristic, a low dielectric constant, and sinterability, in a PZT-based material by using a PZN-based material and PNN-based material. The orientation raw material composition in which the PZNN-based material is solid-solutioned as a relaxor in the PZT-based material may have an empirical formula of (1−x)Pb(Zr_{0.47}Ti_{0.53})O₃-xPb((Ni_{1-y}Zn_{y})_{1/3}Nb_{2/3})O₃. Here, x may have a value in the range of 0.1<x<0.5, preferably, have a value in the range of 0.30≤x≤0.32, and most preferably, have a value of 0.31. In addition, y may have a value in the range of 0.1<x<0.5, preferably have a value in the range of 0.30≤x≤0.41, most preferably have a value of 0.40. In addition, a lead-free piezoelectric material which does not contain lead (Pb) may also be used for the orientation raw material composition. Such a lead-free piezoelectric material may be a lead-free piezoelectric material which includes at least one selected from Bi_{0.5}K_{0.5}TiO₃, Bi_{0.5}Na_{0.5}TiO₃, K_{0.5}Na_{0.5}NbO₃, KNbO₃, NaNbO₃, BaTiO₃, (1−x)Bi_{0.5}Na_{0.5}TiO₃-xSrTiO₃, (1−x)Bi_{0.5}Na_{0.5}TiO₃-xBaTiO₃, (1−x)K_{0.5}Na_{0.5}NbO₃-xBi_{0.5}Na_{0.5}TiO₃, BaZr_{0.25}Ti_{0.75}O₃, etc.

The seed composition is composed of an oxide having a general formula ABO₃, and ABO₃ is an oxide having an orientable plate-like perovskite structure, where A is composed of a bivalent metal element and B is composed a tetravalent metal element. The seed composition composed of an oxide having a general formula ABO₃ may include at least one among CaTiO₃, BaTiO₃, SrTiO₃, PbTiO₃ and Pb(Ti,Zr)O₃. Here, the seed composition may be included in a volume ratio of 1 vol % to 10 vol % based on the orientation raw material composition. When the seed composition is included in a volume ratio of 1 vol % or less, the effect of improving the crystal orientation is minute, and when included in a volume ratio greater than 10 vol %, the piezoelectric performance of the piezoelectric ceramic sintered body decreases.

As described above, the piezoelectric ceramic composition including the orientation raw material composition and the seed composition is grown while having the same orientation as the seed composition through a templated grain growth (TGG) method. That is, BaTiO₃ is used as a seed composition in an orientation raw material composition having the empirical formula 0.69Pb(Zr_{0.47}Ti_{0.53})O₃-0.31Pb((Ni_{0.6}Zn_{0.4})_{1/3}Nb_{2/3})O₃, so that the piezoelectric ceramic sintered body not only can be sintered at a low temperature of 1000° C. or less, but also has a high piezoelectric characteristic similar to a single crystal material because the crystal orientation is improved and the amount of displacement due to an electric field can be maximized.

The seed composition which improves the crystal orientation is added to the orientation raw material composition, and the resultant is sintered to manufacture the piezoelectric ceramic sintered body. Thus, the amount of displacement according to an electric field may be maximized and the piezoelectric characteristics may be remarkably improved.

As described above, in the pressure sensor in accordance with the first exemplary embodiment, the piezoelectric layer 300 is formed between the first and second electrode layers 100 and 200 which are spaced apart from each other, and the piezoelectric layer 300 may be provided with the plurality of single-crystal piezoelectric bodies 310 having predetermined plate-like shapes. Since the plate-like piezoelectric bodies 310 are used, the piezoelectric characteristics are better than that of typical piezoelectric powder. Thus, even a minute pressure may be easily sensed, and the sensing efficiency may thereby be improved.

That is, lead zirconatetita-nate (PZT) ceramic is being widely used for piezoelectric materials mainly used now. The PZT has been improved until now for 80 years or more and is not further improved from the present level. In comparison, a material having an improved physical property is being demanded in fields in which piezoelectric materials are used. A single crystal is a material to meet the demand, and is a new material which can improve the performance of application elements by improving the physical property that has reached the limit by PZT ceramic. The single crystal may have a piezoelectric constant (d₃₃), which is more than two times greater than that of the polycrystal that is the main stream of typical piezoelectric material, and a large electromechanical coupling factor, and exhibit a superior piezoelectric characteristic.

As shown in Table 1 below, it can be found that a piezoelectric single crystal has much greater values of the piezoelectric constants (d₃₃ and d₃₁) and the electromechanical coupling factor (K33) than existing polycrystals. Such a superior physical property exhibits remarkable effects in applying the piezoelectric single crystal to an application device.

TABLE 1

| | polycrystal | single crystal |
|---|---|---|
| d33 [pC/N] | 160-338 | 500 |
| d31 [pC/N] | −50 | −280 |
| Strain [%] | ≈0.4 | ≈1.0 |

Therefore, compared to existing polycrystal ceramic, the piezoelectric single crystal is used for an ultrasonic vibrator in medical and nondestructive inspection, fish detection and the like to enable capturing of a clearer image, an ultrasonic vibrator in a washer to enable stronger oscillation, and for a high-precision control actuator, such as a positioning device in a printer head and a HDD head, and a hand shaking prevention device, to enable more excellent responsibility and miniaturization.

Meanwhile, in order to manufacture a plate-like single crystal piezoelectric body, a solid single crystal growth method, the Bridgemann method, a salt fusion method, or the like may be used. After mixing a single-crystal piezoelectric body manufactured through such a method, the piezoelectric layer may be formed through a method such as printing and molding.

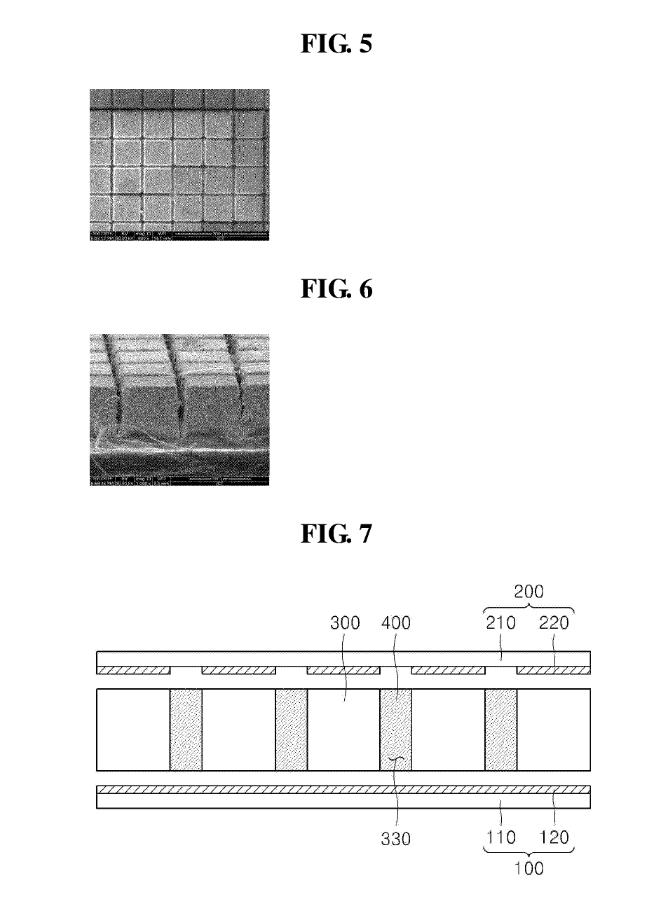

FIG. 4 is a cross-sectional view of a pressure sensor in accordance with a second exemplary embodiment. In addition, FIGS. 5 and 6 are planar and cross-sectional photographs of a pressure sensor in accordance with a second exemplary embodiment.

Referring to FIGS. 4 to 6, a pressure sensor in accordance with a second exemplary embodiment includes: first and second electrode layers 100 and 200 which are spaced apart from each other; and a piezoelectric layer 300 provided between the first and second electrode layers 100 and 200. At this point, the piezoelectric layer 300 may be formed of piezoelectric ceramic having a predetermined thickness. That is, in an exemplary embodiment, a piezoelectric layer 300 is formed such that plate-like piezoelectric bodies 310 are formed in the polymer 320, but in another exemplary embodiment, a piezoelectric layer 300 with a predetermined thickness may be formed by using a piezoelectric ceramic. In addition, the same material as the piezoelectric body 310 may be used for the piezoelectric layer 300. Such a second exemplary embodiment will be described as follows while matters overlapping the descriptions of the first exemplary embodiment are omitted.

The piezoelectric layer 300 may be formed with predetermined widths and predetermined intervals in one direction and another direction facing the one direction. That is, the piezoelectric layer 300 may be divided into a plurality of patterns with predetermined widths and predetermined intervals by a cutaway portion 330 formed to a predetermined depth. At this point, the cutaway portion 330 may include a plurality of first cutaway portions formed with predetermined widths in one direction, and a plurality of second cutaway portions formed with predetermined widths in another direction perpendicular to the one direction. Thus, the piezoelectric layer 300 may be divided into a plurality of unit cells having predetermined widths and predetermined distances by a plurality of first and second cutaway portions as illustrated in FIGS. 5 and 6. At this point, the piezoelectric layer 300 may be cut by the entire thickness, or by 50% to 95% of the entire thickness. That is, the piezoelectric layer 300 is cut away by the entire thickness, or by 50% to 95% of the entire thickness, whereby the cutaway portions may be formed. As such, the piezoelectric layer 300 is cut away, whereby the piezoelectric layer 300 has a predetermined flexible characteristic. At this point, the piezoelectric layer 300 may be cut away so as to have a size of 10 μm to 5,000 μm and an interval of 1 μm to 300 μm. That is, by means of the cutaway portion 330, a unit cell may have a size of 10 μm to 5,000 μm and intervals of 1 μm to 300 μm. Meanwhile, the first and second cutaway portions of the piezoelectric layer 300 may correspond to the intervals between the first and second electrodes 100 and 200. That is, the first cutaway portion may be formed to correspond to the intervals between the first electrodes of the first electrode layer 100, and the second cutaway portion may be formed to correspond to the intervals between the second electrodes of the second electrode layer 200. At this point, the intervals of the electrode layers and the intervals of the cutaway portions may be the same, or the intervals of the electrode layers may be greater than or smaller than the intervals of the cutaway portions. Meanwhile, the cutaway portions may be formed by cutting the piezoelectric layers 300 through a method such as laser, dicing, blade cutting, or the like. In addition, the piezoelectric layer 300 may also be formed by forming cutaway portions by cutting away a material in a green bar state through a method such as laser, dicing, blade cutting, or the like, and then performing a baking process.

FIG. 7 is a cross-sectional view of a pressure sensor in accordance with a third exemplary embodiment.

Referring to FIG. 7, a pressure sensor in accordance with a third exemplary embodiment may include: first and second electrode layers 100 and 200 which are spaced apart from each other; a piezoelectric layer 300 which is provided between the first and second electrode layers 100 and 200 and has a plurality of cutaway portions 330 formed therein in one direction and another direction; and an elastic layer 400 formed in the cutaway portions 330 of the piezoelectric layer 300. At this point, the cutaway portions 330 may be formed over the entire thickness of the piezoelectric layer 300 and formed in a predetermined thickness. That is, the cutaway portions 330 may be formed in a thickness of 50% to 100% of the thickness of the piezoelectric layer 300. Accordingly, the piezoelectric layer 300 may be divided into unit cells spaced predetermined distances apart from each other in one direction and another direction by the cutaway portions 330, and the elastic layer 400 may be formed between the unit cells.

The elastic layer 400 may be formed by using a polymer, silicon, or the like which have elasticity. Since the piezoelectric layer 300 is cut away and the elastic layer 400 is formed, the piezoelectric layer 300 may have a higher flexible characteristic than other exemplary embodiments in which the elastic layer 400 is not formed. That is, when the cutaway portions 330 are formed in the piezoelectric layer 300, but the elastic layer is not formed, the flexible characteristic of the piezoelectric layer 300 may be restricted. However, the piezoelectric layer 300 is entirely cut and the elastic layer 400 is formed, whereby the flexible characteristic may be improved in such a degree that the piezoelectric layer 300 can be rolled. Of course, the elastic layer 400 may be formed such that the cutaway portions 330 are not formed over the entire thickness of the piezoelectric layer 300, but as illustrated in FIGS. 4 to 6, the cutaway portions 330 formed over a portion of the thickness are filled with the elastic layer 400.

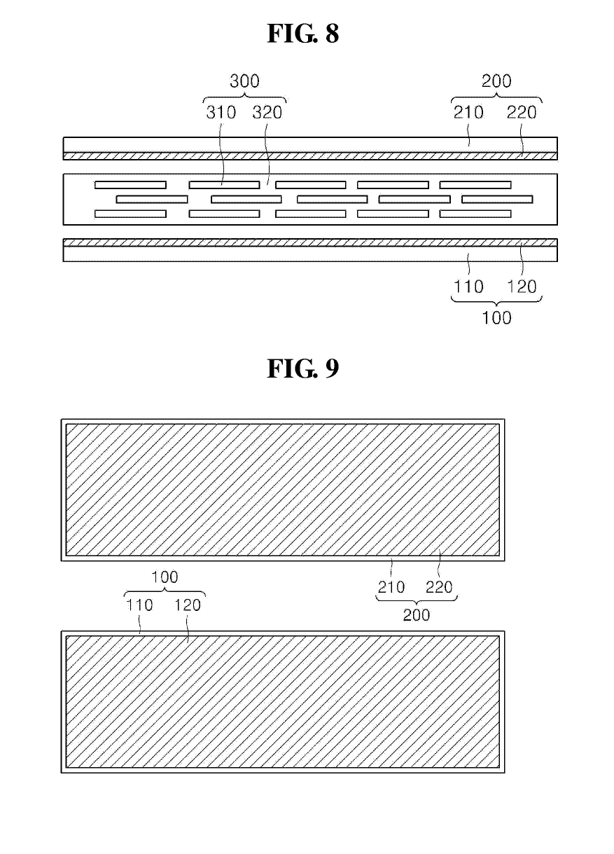

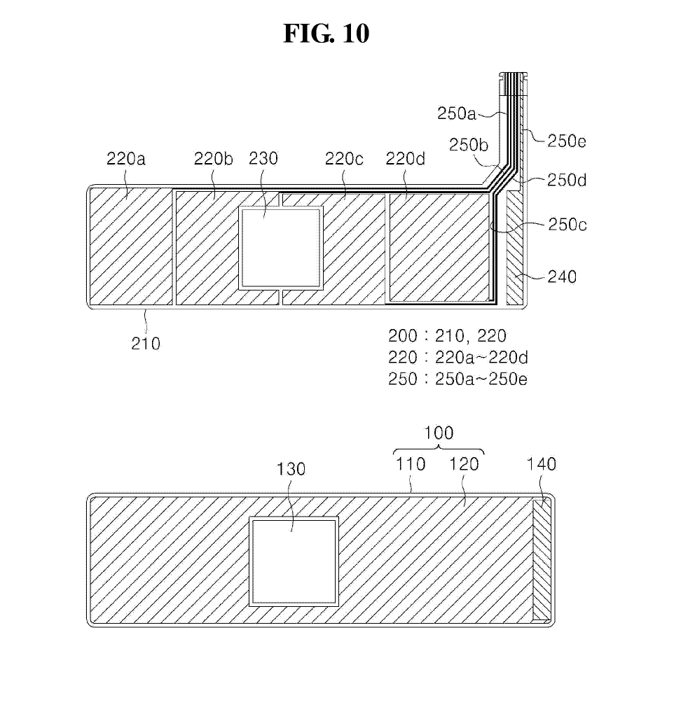

FIG. 8 is a cross-sectional view of a pressure sensor in accordance with a fourth exemplary embodiment, and FIGS. 9 and 10 are schematic plan views of first and second electrode layers in accordance with other exemplary embodiments.

As illustrated in FIG. 8, a pressure sensor in accordance with a fourth exemplary embodiment includes: first and second electrode layers 100 and 200 which are spaced apart from each other; and a piezoelectric layer 300 provided between the first and second electrode layers 100 and 200 and provided with a plurality of plate-like piezoelectric bodies 310 with a predetermined thickness. Here, the first and second electrode layers 100 and 200 may include: first and second support layers 110 and 210, respectively; and first and second electrodes 120 and 220 which are respectively formed on first and second support layers 110 and 210 so as to face each other. That is, the pressure sensor in accordance with the fourth exemplary embodiment has the same configuration as the pressure sensor in accordance with the first exemplary embodiment described by using FIG. 1. However, the first and second electrodes 120 and 220, as illustrated in FIG. 9, may be entirely formed on the first and second support layers 110 and 210. That is, as illustrated in FIGS. 2 and 3, the first and second electrodes 120 and 220 may also be formed to have a predetermined pattern, but as illustrated in FIG. 9, may entirely be formed on the support layers 110 and 210. The first and second electrodes 100 and 200 having such a shape may be applied to a pressure sensor provided to detect a pressure in a local region. That is, in order to detect a pressure in a plurality of regions in an electronic device using a pressure sensor, electrodes 120 and 220 which are formed in predetermined patterns as illustrated in FIGS. 2 and 3 may be used, and to detect a pressure in a local region, the electrodes 120 and 220 which are entirely formed on the support layers 110 and 210 as illustrated in FIG. 9 may be used.

In addition, in the case in which the electrodes 120 and 220 which are entirely formed on the support layers 110 and 210 are used, the piezoelectric layer 300 may be formed in the shapes illustrated in FIGS. 4 to 7. That is, as illustrated in FIGS. 4 to 6, a predetermined cutaway portion 330 may also be formed in the piezoelectric layer 300, and as illustrated in FIG. 7, the elastic layer 400 may also be formed in the cutaway portions 330.

Meanwhile, the pressure sensor in accordance with an exemplary embodiment may have openings 130 and 230 in predetermined regions. That is, as illustrated in FIG. 10, first and second electrode layers 100 and 200 may be formed in predetermined shapes, and openings 130 and 230 may be formed in predetermined regions of the first and second electrode layers 100 and 200. The openings 130 and 230 may be provided such that another pressure sensor or a functional part having a different function from the pressure sensor may be inserted therethrough. At this point, although not shown, also in the piezoelectric layer 300, an opening overlapping the openings formed in the first and second electrode layers 100 and 200 may be formed. Meanwhile, the first and second electrodes 100 and 200 may also be formed in shapes different from each other. That is, as illustrated in FIG. 10, the first electrode layer 100 may have a first electrode 120 formed entirely on a first support layer 110, and the second electrode layer 200 may have a plurality of second electrodes 220 which are spaced a predetermined distance apart from each other on a second support layer 210. For example, the second electrodes 210 may be provided such that a first region 210a with an approximately rectangular shape, second and third regions 220b and 220c which have approximately rectangular shapes and are formed with the opening 230 therebetween, and a fourth region 220d formed in an approximately rectangular shape are spaced predetermined distances apart from each other. In addition, a first connection pattern 140 may be formed on the first support layer 110, and a second connection pattern 240 may be formed on the second support layer 210. At this point, the first connection pattern 140 is formed in contact with the first electrode 110, and the second connection pattern 240 is formed spaced apart from the fourth region 220d. In addition, the first and second connection patterns 140 and 240 may be formed so as to partially overlapping each other. Of course, although not shown, a third connection pattern may be formed between the first and second connection patterns 140 and 240 on at least portion of the piezoelectric layer 300 between the first and second electrode layers 100 and 200. That is, the third connection pattern may be formed spaced apart from the piezoelectric layer 300. Accordingly, the first and second connection patterns 140 and 240 may be connected through the third connection pattern. In addition, in the second electrode layer 200, first to fourth extending patterns 250a, 250b, 250c, and 250d may respectively be formed by extending from the first to fourth regions 210a to 210d, and a fifth extending pattern 250e may be formed by extending from the second connection pattern 240. The first to fifth extending patterns 250a to 250d may extend to a connector (not shown) and be connected to a control unit or power supply unit. Accordingly, a predetermined power supply such as a ground power supply may be applied to the first connection pattern 140 through the fifth extending pattern 250e, the second connection pattern 240, and the third connection pattern. In addition, the power sensed by the first to fourth regions 220a to 220d may be transferred to the connector through the first to fourth extending patterns 250a to 250d. Of course, a predetermined power source such as a driving power source may be applied to the first to fourth regions 220a to 220d through the first to fourth extending patterns 250a to 250d.

The pressure sensors in accordance with the above exemplary embodiments may be provided in electronic devices such as smart phones and detect a touch or an input of a user. An electronic device provided with a pressure sensor in accordance with exemplary embodiments will be described as follows using drawings.

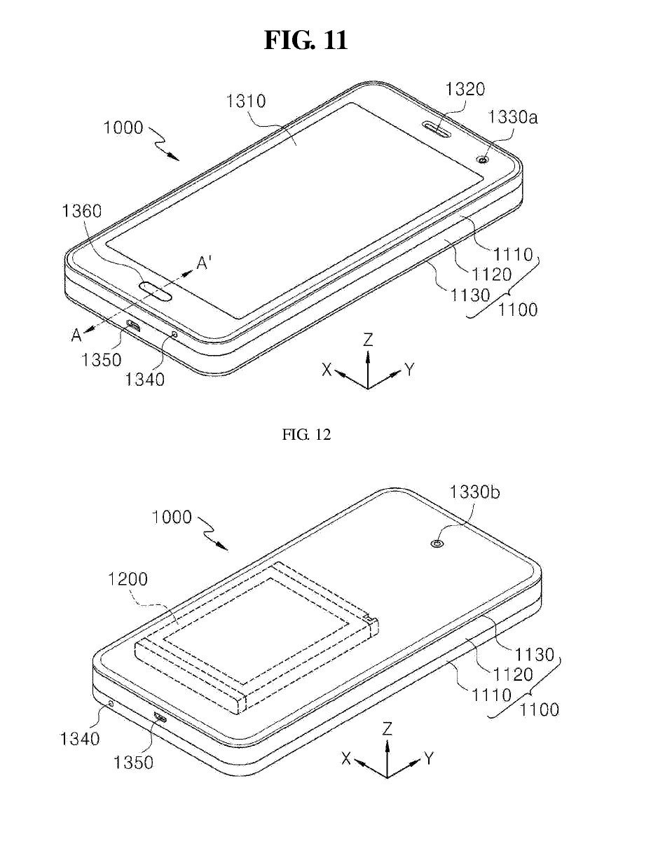

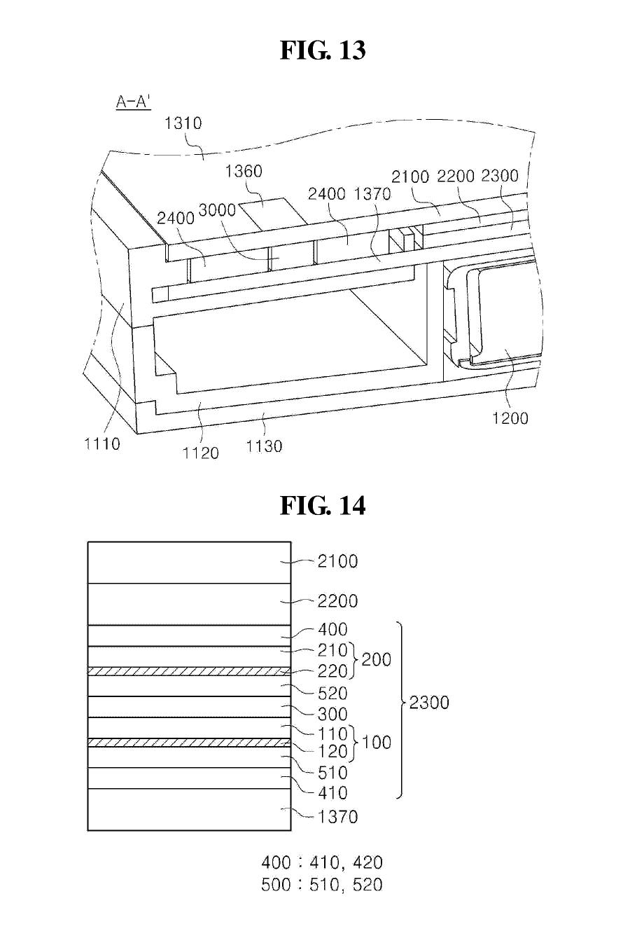

FIGS. 11 and 12 are a front perspective view and a rear perspective view of an electronic device provided with a pressure sensor in accordance with an exemplary embodiment, and FIG. 13 is a partial cross-sectional view taken along line A-A′ of FIG. 11. Here, the exemplary embodiment may be described using a mobile terminal including a smart phone as an example of an electronic device provided with a pressure sensor, and FIGS. 11 to 13 schematically illustrate main portions related to the exemplary embodiment.

Referring to FIGS. 11 to 13, an electronic device 1000 includes a case 1100 forming an outer appearance and a plurality of functional modules, circuits, and the like for performing a plurality of functions of the electronic device 1000 are provided inside the case 1100. The case 1100 may include a front case 1110, a rear case 1120, and a battery cover 1130. Here, the front case 1110 may form portions of the upper portion and the side surface of the electronic device 1000, and the rear case 1120 may form portions of the side surface and the lower portion of the electronic device 1000. That is, at least a portion of the front case 1110 and at least a portion of the rear case 1120 may form the side surface of the electronic device 1000, and a portion of the front case 1110 may form a portion of the upper surface except for a display part 1310. In addition, the battery cover 1130 may be provided to cover the battery 1200 provided on the rear case 1120. Meanwhile, the battery cover 1130 may be integrally provided or detachably provided. That is, when the battery 1200 is an integral type, the battery cover 1130 may be integrally formed, and when the battery 1200 is detachable, the battery cover 1130 may also be detachable. Of course, the front case 1110 and the rear case 1120 may also be integrally manufactured. That is, the case 1100 is formed such that the side surface and the rear surface are closed regardless of the front case 1110 and the rear case 1120, and the battery cover 1130 may be provided to cover the rear surface of the case 1100. Such a case 1100 may have at least a portion formed through injection molding of a synthetic resin and may be formed of a metal material. That is, at least portions of the front case 1110 and the rear case 1120 may be formed of a metal material, and for example, a portion forming the side surface of the electronic device 1000 may be formed of a metal material. Of course, the battery cover 1130 may also be formed of a metal material. Metal materials used for the case 1100 may include, for example, stainless steel (STS), titanium (Ti), aluminum (Al) or the like. Meanwhile, in a space formed between the front case 1110 and the rear case 1120, various components, such as a display part such as a liquid crystal display device, a pressure sensor, a circuit board, a haptic device, may be incorporated.

In the front case 1110, a display part 1310, a sound output module 1320, a camera module 1330a, and the like may be disposed. In addition, on one surface of the front case 1110 and the rear case 1120, a microphone 1340, an interface 1350 and the like may be disposed. That is, on the upper surface of the electronic device 1000, the display part 1310, the sound output module 1320, the camera module 1330a and the like may be disposed, and on one side surface of the electronic device, that is, on the lower side surface, the microphone 1340, the interface 1350, and the like may be disposed. The display part 1310 is disposed on the upper surface of the electronic device 1000 and occupies the most of the upper surface of the front case 1110. That is, the display part 1310 may be provided in an approximately rectangular shape respectively having predetermined lengths in X- and Y-directions, includes the central region of the upper surface of the electronic device 1000, and is formed on most of the upper surface of the electronic device 1000. At this point, between the outer contour of the electronic device 1000, that is, the outer contour of the front case 1110, and the display part 1310, a predetermined space which is not occupied by the display part 1310 is provided, and the sound output module 1320. In the space, in the X-direction, the camera module 1330a are provided above the display part 1310, and a user input part including a front side surface input part 1360 may be provided below the display part 1310. In addition, between two edges of the display part 1310, which extend in the X-direction, and the periphery of the electronic device 1000, that is, between the display part 1310 and the electronic device 1000 in the Y-direction, a bezel region may be provided. Of course, a separate bezel region may not be provided, and the display part 1310 may be provided to extend up to the periphery of the electronic device 1000 in the Y-direction.

The display part 1310 may output visual information and receive touch information from a user. To this end, the display part 1310 may be provided with a touch input device. The touch input device may include: a window 2100 which covers the front surface of the terminal body; a display part 2200 such as a liquid crystal display device; and a first pressure sensor 2300 with which touch or pressure information of a user is input in accordance with at least one of the exemplary embodiments. In addition, the touch input device may further include a touch sensor provided between the window 2100 and the display part 2200. That is, the touch input device may include a touch sensor and a first pressure sensor 2300. For example, the touch sensor may be formed such that a plurality of electrodes are formed to be spaced apart from each other in one direction and another direction perpendicular to the one direction on a transparent plate with a predetermined thickness, and a dielectric layer is provided therebetween and may detect a touch input from the user. That is, the touch sensor may have the plurality of electrodes disposed, for example, in a lattice shape, and detect the electrostatic capacitance according to the distance between the electrodes due to the touch input of the user. Here, the touch sensor may detect coordinates in the horizontal direction of user's touch, that is, in the X- and Y-directions perpendicular each other, and the first pressure sensor 2300 may detect coordinates not only in the X- and Y-directions, but also in the vertical direction, that is, in the Z-direction. That is, the touch sensor and the first pressure sensor 2300 may simultaneously detect coordinates in the X- and Y-directions, and the first pressure sensor 2300 may further detect the coordinate in the Z-direction. As such, the touch sensor and the first pressure sensor 2300 simultaneously detects the horizontal coordinates, and the first pressure sensor 2300 detects the vertical coordinate, whereby the touch coordinate of the user may be more precisely detected.

Meanwhile, in regions besides the display part 1310 on the upper surface of the front case 1110, the sound output module 1320, the camera module 1330a, the front surface input part 1360, and the like may be provided. At this point, the sound output module 1320 and the camera module 1330a may be provided above the display part 1310, and the user interface part such as the front surface input part 1360 may be provided below the display part 1310. The front surface input part 1360 may be configured from a touch key, a push key, or the like, and a configuration is also possible by using a touch sensor or a pressure sensor without the front surface input part 1360. At this point, in an inner lower portion of the front surface input part 1360, that is, inside the case 1100 below the front surface input part 1360 in the Z-direction, a functional module 3000 for functions of the front surface input part 1360 may be provided. That is, according to a driving method of the front surface input part 1360, a functional module which performs the functions of a touch key or a push key may be provided, and a touch sensor or a pressure sensor may be provided. In addition, the front surface input part 1360 may include a fingerprint recognition sensor. That is, the fingerprint of the user may be recognized through the front surface input part and whether the user is a legal user may be detected, and to this end, the functional module 3000 may include a fingerprint recognition sensor. Meanwhile, in the Y-direction on one side and the other side of the front surface input part, a second pressure sensor 2400 may be provided. The second pressure sensors 2400 are provided on both sides of the front surface input part 1360 as a user interface, so that a function of detecting the user's touch and returning to the previous screen and a setting function for screen setting of the display part 1310 may be performed. At this point, the front surface input part 1360 using the fingerprint recognition sensor may perform not only the fingerprint recognition of a user but also the function of returning to the initial screen. Meanwhile, a haptic feedback device such as a piezoelectric vibration device which contacts the display part 1310 may further be provided and provide a feedback by responding to an input or a touch of the user. Such a haptic feedback device may be provided in a predetermined region of the electronic device 1000 except for the display par 1310. For example, the haptic feedback device may be provided in an outside region of the sound output module 1310, an outside region of the front surface input part 1360, a bezel region, or the like. Of course, the haptic feedback device may be provided below the display part 1310.

On the side surface of the electronic device 1000, although not shown, a power supply part and a side surface input part may further be provided. For example, the power supply part and the side surface input part may respectively be provided on two side surfaces facing each other in the Y-direction in the electronic device, and may also be provided on one side surface so as to be spaced apart from each other. The power supply part may be used when turning on or off the electronic device, and be used when enabling or disabling a screen. In addition, the side surface input part may be used to adjust the loudness or the like of a sound output from the sound output module 1320 and the like. At this point, the power supply part and the side surface input part may be configured from a touch key, a push key, or the like, and also be configured from a pressure sensor. That is, the electronic device in accordance with an exemplary embodiment may be provided with pressure sensors in a plurality of regions besides the display part 1310. For example, at least one pressure sensor may further be provided for detecting a pressure of sound output module 1320, the camera module 1330a, or the like on the upper side of the electronic device, controlling a pressure of the front surface input part 1360 on the lower side of the electronic device, controlling a pressure of the power supply part and side surface input part on the side surface of the electronic device.

Meanwhile, on the rear surface, that is, the rear case 1120 of the electronic device 1000, as illustrated in FIG. 12, a camera module 1330b may be further mounted. The camera module 1330b may be a camera which has a capturing direction substantially opposite that of the camera module 1330a, and has pixels different from those of the camera module 1330a. A flash (not shown) may additionally be disposed adjacent to the camera module 1330b. In addition, although not shown, a fingerprint recognition sensor may be provided under the camera module 1330b. That is, the front surface input part 1360 is not provided with a fingerprint recognition sensor, and the fingerprint recognition sensor may also be provided on the rear surface of the electronic device 1000.

The battery 1200 may be provided between the rear case 1120 and the battery cover 1300, also be fixed, or also be detachably provided. At this point, the rear case 1120 may have a recessed region corresponding to a region in which the battery 1200 is inserted, and may be provided such that after the battery 1200 is mounted, the battery cover 1200 covers the battery 1200 and the rear case 1120.

In addition, as illustrated in FIG. 13, a bracket 1370 is provided inside the electronic device 1000 between the display part 1310 and the rear case 1130, and the window 2100, the display section 2200, and the pressure sensor 2300 may be provided above the bracket 1370. That is, above the bracket 1370 of the display part 1310, a touch input device in accordance with an exemplary embodiment may be provided, and the bracket 1370 supports the touch input device. In addition, the bracket 1370 may extend to a region besides the display part 1310. That is, as illustrated in FIG. 13, the bracket 1370 may extend to a region in which the front surface input part 1360 and the like are formed. In addition, at least a portion of the bracket 1370 may be supported by a portion of the front case 1110. For example, the bracket 1370 extending outside the display part 1310 may be supported by an extension part extending from the front case 1110. In addition, a separation wall with a predetermined height may also be formed on the bracket 1370 in a boundary region between the display part 1310 and the outside thereof. The bracket 1370 may support the pressure sensor 2400 and the functional module 3000 such as the fingerprint recognition sensor. In addition, although not shown, there may be provided, on the bracket 1370, a printed circuit board (PCB) or a flexible printed circuit board (FPCB) provided with at least one driving means for supplying power to the functional module 3000 such as the pressure sensors 2300 and 2400 and the fingerprint recognition sensor, receiving signals output therefrom, and detecting the signals.

As described above, at least one pressure sensor in accordance with an exemplary embodiment may be provided in a predetermined region in the electronic device. For example, as described above, the pressure sensors may be provided respectively in the display part 1310 and a user input part, and also be provided in any one thereamong. However, at least one or more of the pressure sensors may be provided in a predetermined region in the electronic device. As such, various examples in accordance with exemplary embodiments in which pressure sensors may be provided in a plurality of regions will be described as follows.

FIG. 14 is a cross-sectional view of an electronic device in accordance with a second exemplary embodiment, and is a cross-sectional view of a touch input device provided in the display part 1310.

Referring to FIG. 14, an electronic device in accordance with the second exemplary embodiment includes a window 2100, a display section 2200, a pressure sensor 2300, and a bracket 1370.

The window 2100 is provided on the display section 2200 and is supported by at least a portion of a front case 1110. In addition, the window 2100 forms the upper surface of the electronic device and is to be in contact with an object such as a finger and a stylus pen. The window 2100 may be formed of a transparent material, for example, may be manufactured by using acryl resin, glass, or the like. Meanwhile, the window 2100 may be formed not only on the display part 1310 but also on the upper surface of the electronic device 1000 outside the display part 1310. That is, the window 2100 may be formed so as to cover the upper surface of the electronic device 1000.

The display section 2200 displays an image to a user through the window 2100. The display section 2200 may include a liquid crystal display (LCD) panel, an organic light emitting display (OLED) panel, or the like. When the display section 2200 is a liquid crystal display panel, a backlight unit (not shown) may be provided below the display section 2200. The backlight unit may include a reflective sheet, a light guide plate, an optical sheet, and a light source. A light-emitting diode (LED) may be used as the light source. At this point, the light source may be provided under an optical structure in which the reflective sheet, the light guide plate, and the optical sheet are stacked, or may also be provided on a side surface. A liquid crystal material of the liquid crystal display panel reacts with the light source of the backlight unit and outputs a character or an image in response to an input signal. Meanwhile, a light-blocking tape (not shown) is attached between the display section 2200 and the backlight unit and blocks the light leakage. The light-blocking tape may be configured in a form in which an adhesive is applied on both side surfaces of a polyethlene film. The display section 2200 and the backlight unit are adhered to the adhesive of the light-blocking tape, and the light from the backlight unit is prevented from leaking to the outside of the display section 2200 by the polyethylene film inserted in the light-blocking tape. Meanwhile, when the backlight unit is provided, the pressure sensor 2300 may be provided under the backlight unit, and also be provided between the display section 2200 and the backlight unit.

The pressure sensor 2300 may include: first and second electrode layers 100 and 200; and a piezoelectric layer 300 provided between the first and second electrode layers 100 and 200. The first and second electrode layers 100 and 200 may include: first and second support layers 110 and 210; and first and second electrodes 120 and 220 which are respectively formed on the first and second support layers 110 and 210 and has at least any one among the shapes described by using FIGS. 1 to 9. At this point, the first and second electrodes 120 and 220 may be provided so as to face each other with the dielectric layer 300 disposed therebetween. However, as illustrated in FIG. 14, the first and second electrodes 120 and 220 may be formed such that any one thereof faces the piezoelectric layer 300 and the other does not face the piezoelectric layer 300. That is, the first electrode layer 100 may be formed such that the first electrode 120 is formed under a first support layer 110 and does not face the piezoelectric layer 300, and the second electrode layer 200 may be formed such that the second electrode 220 is formed under a second support layer 210 and faces the piezoelectric layer 300. In other words, upwardly from the bottom side, the first electrode 120, the first support layer 110, the piezoelectric layer 300, the second electrode 220, and the second support layer 210 are formed in this order. In addition, the pressure sensor 2300 may have adhesive layers 410, 420; 400 on the lowermost layer and the uppermost layer. The adhesive layers 410 and 420 may be provided for adhering and fixing the pressure sensor 2300 between the display section 2200 and the bracket 1370. A double-sided adhesive tape, an adhesive tape, an adhesive, or the like may be used for the adhesive layers 410 and 420. In addition, a first insulating layer 510 may be provided between the first electrode layer 100 and the adhesive layer 410, and a second insulating layer 520 may be provided between the piezoelectric layer 300 and the second electrode 220. The insulating layers 510, 520; 500 may be formed by using a material having an elastic force and a restoring force. For example, the insulating layers 510 and 520 may be formed by using silicone, rubber, gel, a teflon tape, urethane, or the like which has a hardness of 30 or less. In addition, a plurality of pores may be formed in the insulating layers 510 and 520. The pores may have sizes of 1 μm to 500 μm and may be formed in a porosity of 10% to 95%. The plurality of pores are formed in the insulating layers 510 and 520, whereby the elastic force and the restoring force of the insulating layers 510μ and 520 may further be improved. Here, the first and second support layers 110 and 210 may respectively be formed in thicknesses of 50 μm to 150 μm, the first and second electrodes may respectively be formed in thicknesses of 1 μm to 50 μm, and the piezoelectric layer 300 may be formed in a thickness of 10 μm to 1,000 μm. That is, the piezoelectric layer 300 may be formed to be the same as or thicker than the first and second electrode layers 100 and 200, and the first and second electrode layers 100 and 200 may be formed in the same thickness. However, the first and second electrode layers 100 and 200 may be formed in thicknesses different from each other. For example, the second electrode layer 200 may be formed in a smaller thickness than the first electrode layer 100. In addition, the first and second insulating layers 510 and 520 may respectively be formed in thicknesses of 3 μm to 500 μm, and the first and second adhesive layers 410 and 420 may respectively be formed in thicknesses of 3 μm to 1000 μm. At this point, the first and second insulating layers 510 and 520 may be formed in the same thickness, and the first and second adhesive layers 410 and 420 may be formed in the same thickness. However, the insulating layers 510 and 520 are formed in thicknesses different from each other, and the first and second adhesive layers 410 and 420 may be formed in thicknesses different from each other. For example, the first adhesive layer 410 may be formed thicker than the second adhesive layer 420.

As illustrated in FIG. 13, the bracket 1370 is provided over the rear case 1120. The bracket 1370 supports the touch sensor, the display section 2200, and the pressure sensor 2300, which are provided over the bracket, and prevents the pressing force of an object from being scattered. Such a bracket 1370 may be formed of a material the shape of which is not deformed. That is, the bracket 1370 prevents the scattering of the pressing force of an object, and supports the touch sensor, the display section 2200, and the pressure sensor 2300, and may therefore be formed of a material the shape of which is not deformed by a pressure. At this point, the bracket 1370 may be formed of a conductive material or an insulating material. In addition, the bracket 1370 may be formed in a structure in which an edge or the entire portion thereof is bent, that is, in a bent structure. As such, by providing the bracket 1370, the pressing force of an object is not scattered but concentrated, and thus, a touch region may be more precisely detected.

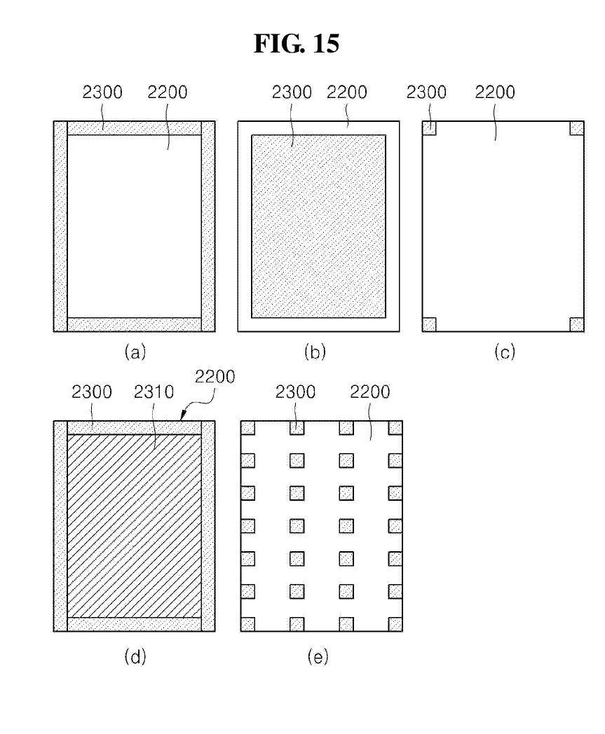

Meanwhile, the pressure sensor may be formed on the entire region under the display section 2200 and may also be formed on at least a portion under the display section 2200. Such a disposition form of the pressure sensor is illustrated in FIG. 15. FIG. 15 is a schematic plan view illustrating a disposition form of a pressure sensor in an electronic device in accordance with a second exemplary embodiment, and illustrates a disposition form of a pressure sensor 2300 with respect to a display section 2200.

As illustrated in (a) of FIG. 15, a pressure sensor 2300 may be provided along the periphery of the display section 2200. At this point, the pressure sensor 2300 may be provided with a predetermined width from the periphery, that is, from the edge, of the approximately rectangular display section 2200, and provided in a predetermined length. That is, pressure sensors 2300 with a predetermined width may be provided along two long sides of the display section 2200, and pressure sensors 2300 with a predetermined width may be provided along two short sides of the display section 2200. Accordingly, four pressure sensors 2300 may be provided along the periphery of the display section 2200, or one pressure sensor 2300 may also be provided along the shape of the periphery of the display section 2200.

As illustrated in (b) of FIG. 15, the pressure sensor 2300 may be provided in regions except for a predetermined width of the periphery of the display section 2200.

As illustrated in (c) of FIG. 15, the pressure sensor 2300 may be provided in regions at which two adjacent sides of the display section 2200 meet, that is, in corner regions. That is, the pressure sensor 2300 may be provided in four corner regions of the display section 2200.

As illustrated in (d) of FIG. 15, the pressure sensors 2300 are provided in the peripheral regions of the display section 2200, and a filling member 2310 such as a double-sided tape may be provided in the remaining regions in which the pressure sensors 2300 are not provided.

As illustrated in (e) of FIG. 15, a plurality of pressure sensors 2300 may be provided at approximately regular intervals under the display section 2200.

Of course, in (a), (c), and (d) of FIG. 15, the filling member 2310 such as a double-sided tape may be provided in regions in which the pressure sensor 2300 is not provided.

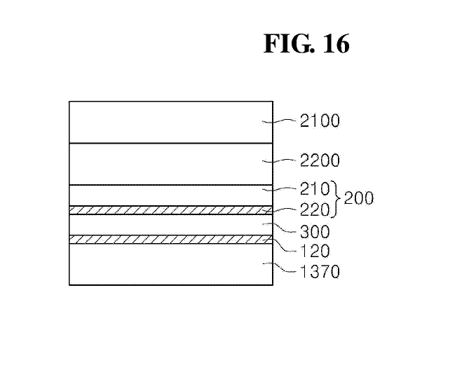

Meanwhile, any one of the first and second electrode layers 100 and 200 of the exemplary embodiment may be provided on the bracket 1370. That is, the bracket 1370 may function as the first and second electrode layers 100 and 200. In this case, a first electrode 120 or a second electrode 220 may be formed on the bracket 1370. Accordingly, the bracket 1370 may be used as a support layer for the first electrode layer 100 or the second electrode layer 200. FIG. 16 illustrates an electronic device provided with a pressure sensor in accordance with a third exemplary embodiment. FIG. 16 illustrates a case in which a first electrode 120 is formed on a bracket 1370. At this point, although not shown, a touch sensor may further be provided between a window 2100 and a display section 2200.

The bracket 1370 may be used as a first electrode layer. That is, the bracket 1370 may be used as a ground electrode. As such, in order to be used as a first electrode layer, that is, as a ground electrode, the bracket 1370 may be formed of an insulating material, and a first electrode 120 may be formed on the bracket 1370. Such a first electrode 120 may be arranged in one direction so as to have a predetermined width and interval, and also be formed in a predetermined pattern. In addition, the first electrode 120 may entirely be formed on the bracket 1370. At this point, the first electrode 120 on the bracket 1370 may be formed so as to at least partially overlap a second electrode 220 of a second electrode layer 200. That is, the first and second electrodes 120 and 220 may be formed to overlap each other such that for example, power is generated from a piezoelectric layer 300 between the first electrode 120 and the second electrode 220. For example, according to the application of a touch or a pressure from a user, at least a portion of the second electrode 220 applies a pressure to at least a portion of the piezoelectric layer 300, and accordingly, power may be generated from the piezoelectric layer 300 to which the pressure is applied. Meanwhile, the first electrode 120 formed on the bracket 1370 may be formed of a transparent conductive material. However, the first electrode 120 may also be formed of an opaque conductive material such as copper, silver, or gold. A ground potential may be applied to such a bracket 1370 through the first electrode 120. That is, a signal with a predetermined potential may be applied through the second electrode layer 200, and a ground potential may be applied through the bracket 1370. Accordingly, due to a touch of an object, the distance between the second electrode layer 200 and the bracket 1370 becomes smaller than a reference distance, and accordingly, predetermined power may be generated in the piezoelectric layer 300 between the second electrode layer 200 and the bracket 1370.

Meanwhile, in the above exemplary embodiments, a case has been illustrated in which the pressure sensor 2300 has been provided between the display section 2200 and the bracket 1370. However, the pressure sensor 2300 may also be provided between the window 2100 and the display section 2200, and also be provided between the display section 2200 and the backlight unit.

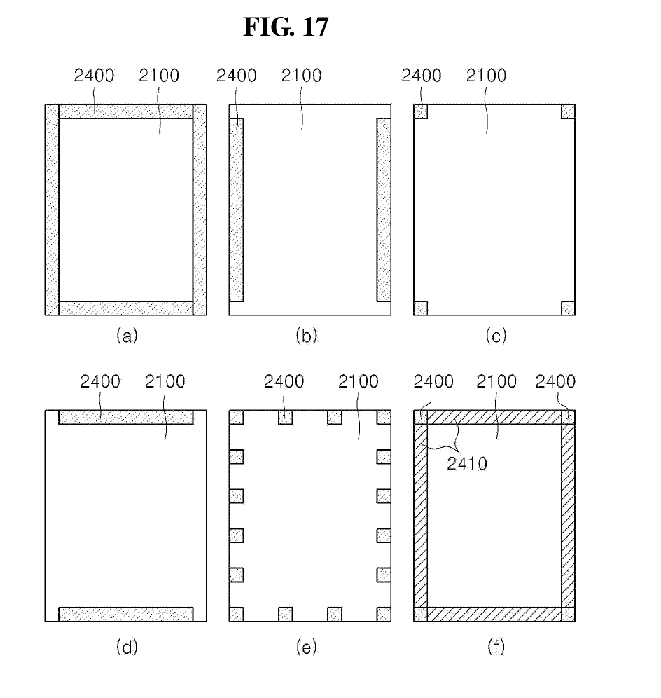

In addition, the pressure sensor may also be provided in a region besides the display part 1310. At this point, at least one pressure sensor may be provided in a region besides the display part 1310, and such a disposition form is illustrated in FIG. 17. FIG. 17 is a schematic plan view illustrating a disposition form of pressure sensors in an electronic device in accordance with a fourth exemplary embodiment, and illustrates a disposition form of the pressure sensors 2400 with respect to a window 2100.

As illustrated in (a) of FIG. 17, pressure sensors 2400 may be provided along the periphery of the window 2100. At this point, the pressure sensors 2400 may be provided with predetermined widths from the periphery of the approximately rectangular window 2100, that is, from the edge, and in predetermined lengths. That is, pressure sensors 2400 with a predetermined width may be provided along two long sides of the window 2100, and pressure sensors 2400 with a predetermined width may be provided along two short sides of the window 2100. In other words, the pressure sensor 2400 may be provided in a region other than the display part 1310, that is, in lower and upper side regions of the display part 1310 and in a bezel region At this point, four pressure sensor 2400 may be provided along the edges of the window 2100, and one pressure sensor may also be provided along the shape of the edges of the window 2100.

As illustrated in (b) of FIG. 17, pressure sensors 2400 may be provided along the long-side edges of the window 2100. That is, the pressure sensors 2400 may be provided in a region between the edges of the display part 1310 and the periphery of an electronic device 1000, that is, in a bezel region.

As illustrated in (c) of FIG. 17, pressure sensors 2400 may be provided in regions at which two adjacent sides of the window 2100 meet, that is, in corner regions. That is, the pressure sensor 2400 may be provided in four corner regions of the window 2100.

As illustrated in (d) of FIG. 17, pressure sensors 2400 may be provided along the short-side edges of the window 2100.

As illustrated in (e) of FIG. 17, a plurality of pressure sensors 2400 may be provided on short-side and long-side edges of a window 2100 so as to be spaced a predetermined distance apart from each other. At this point, the plurality of pressure sensors 2400 may be provided at approximately regular intervals.

As illustrated in (f) of FIG. 17, pressure sensors 2400 may be respectively provided on four corner regions of a window 2100, and filling members 2410 such as adhesive tapes are provided in a region between the pressure sensors 2400, that is, in long-side and short-side edge regions.

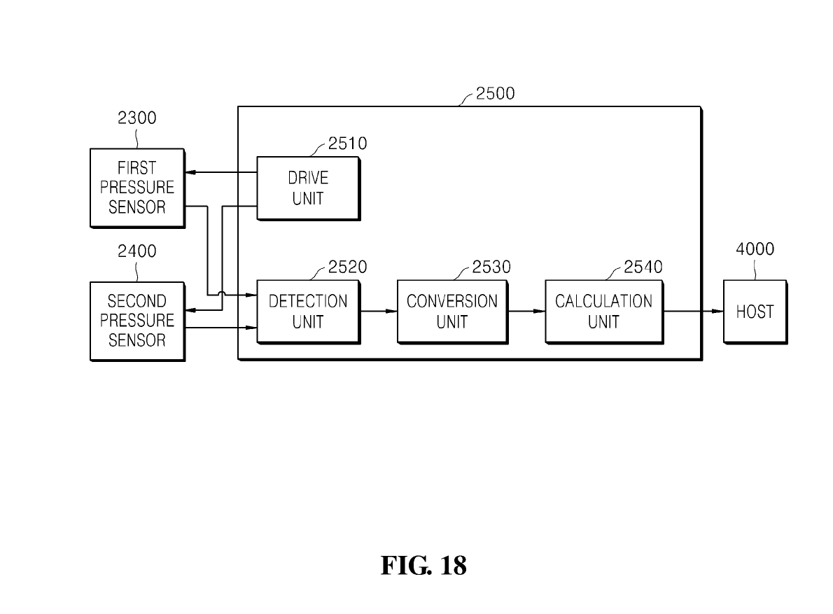

FIG. 18 is a control configuration diagram of a pressure sensor in accordance with an exemplary embodiment, and is a control configuration diagram including first and second pressure sensors 2300 and 2400.

Referring to FIG. 18, the control configuration of a pressure sensor in accordance with an exemplary embodiment may include a control unit 2500 which controls the operation of at least any one of a first pressure sensor 2300 and a second pressure sensor 2400. The control unit 2500 may include a driving unit 2510, a detection unit 2520, a conversion unit 2530, and a calculation unit 2540. At this point, the control unit 2500 including the driving unit 2510, the detection unit 2520, the conversion unit 2530, and the calculation unit 2540 may be provided as one integrated circuit (IC). Accordingly, at least one output of the pressure sensors 2300 and 2400 may be processed by using one integrated circuit (IC).

The driving unit 2510 applies a driving signal to the one or more pressure sensor 2300 and 2400. That is, the driving unit 2510 may apply a driving signal to the first pressure sensor 2300 and the second pressure sensor 2400, or apply a driving signal to the first pressure sensor 2300 or the second pressure sensor 2400. To this end, the driving unit 2510 may include: a first driving unit for driving the first pressure sensor 2300; and a second driving unit for driving the second pressure sensor 2400. However, the driving unit 2510 may be configured as one unit and may apply a driving signal to the first and second pressure sensors 2300 and 2400. That is, the single driving unit 2510 may apply a driving signal to each of the first and second pressure sensors 2300 and 2400. When the first and second pressure sensors 2300 and 2400 are configured in plurality, the driving unit 2510 may apply a driving signal to the plurality of pressure sensors 2300 and 2400. In addition, the driving signal from the driving unit 2510 may be applied to any one of the first and second electrodes 120 and 220 constituting the first and second pressure sensors 2300 and 2400. For example, the driving unit 2510 may apply, for example, a ground signal to the first electrode 120. Of course, the driving unit 2510 may also apply a predetermined driving signal to the second electrode 220. At this point, the driving signals applied to the first and second pressure sensors 2300 and 2400 may be the same as or different from each other. The driving signal may be a square wave, a sine wave, a triangle wave, or the like which has predetermined period and amplitude, and may be sequentially applied to each of the plurality of first electrodes 120. Of course, the driving unit 2510 may apply a driving signal simultaneously to the plurality of first electrodes 120 or also optionally apply the driving signal to only a portion among the plurality of first electrodes 120.

The detection unit 2520 detects output signals of the pressure sensors 2300 and 2400. For example, when a ground potential is applied to the first electrode 120, and a pressure is applied by user's touch to the piezoelectric layer 300 from the second electrode 220 in at least one region, a predetermined power is generated from the piezoelectric layer 300 of the corresponding region. Thus, the detection unit 2520 detects the power output from a predetermined region of the pressure sensors 2300 and 2400, for example, from the second electrode 220 or the piezoelectric layer 300, thereby detecting a pressure. Here, the detection unit 2520 may include first and second detection units for detecting the power of the first and second pressure sensors 2300 and 2400, respectively. However, the single detection unit 2520 may detect the power of all the first and second pressure sensors 2300 and 2400, and to this end, the detection unit 2520 may sequentially detect the power of the first and second pressure sensors 2300 and 2400. As such, the detection unit 2520 may detect the power of the first and second pressure sensors 2300 and 2400 and detect a touched region and the pressure of the region. For example, when a user touches with a finger, the center of the finger touches a region, and thus, there may be a central region to which the strongest pressure is transferred and a peripheral region to which a pressure weaker than the strongest pressure is transferred. The touch pressure of the user is most strongly transferred to the central region. Accordingly, the pressure applied to the piezoelectric layer 300 is high in the central region, and in the peripheral region the pressure applied to the piezoelectric layer 300 becomes small. Thus, the power output from the central region is higher than from the peripheral region. Accordingly, by detecting and comparing the power output from a plurality of regions, the central region to which the strongest pressure is transferred, and the peripheral region to which a pressure weaker than the strongest pressure is transferred may be detected, and consequently, a region to be touched by the user may be determined and detected as the central region. Of course, the region which has not been touched by the user may output lower power than the peripheral region or may not output power. Meanwhile, such a detection unit 2520 may include a plurality of C-V converters (not shown) provided with at least one calculation amplifier and at least one capacitor, and the plurality of C-V converters may be respectively connected to a plurality of second electrodes 220 of the first and second pressure sensors 2300 and 2400. The plurality of C-V converters may output a converted analog signal, and to this end, each of the C-V converters may include an integration circuit. Meanwhile, when a driving signal is sequentially applied to the plurality of second electrodes from the drive part 2510, since power may be detected from the plurality of first electrodes, the C-V converters of the number of the plurality of first electrodes may be provided.

The conversion unit 2530 converts the analog signal output from the detection unit 2520 into a digital signal and generates a detection signal. For example, the conversion unit 2530 may include: a time-to-digital converter (TDC) circuit which measures the time until the analog signal output from the detection unit 2520 reaches a predetermined reference voltage level and converts the time into a detection signal, as a digital signal; or an analog-to-digital (ADC) circuit which measures the amount of change in the level of the analog signal output from the detection unit 2520 for a predetermined time, and converts the amount into a detection signal, as a digital signal.

The calculation unit 2540 determines the touch pressure applied to the first and second pressure sensors 2300 and 2400 using the detection signal. The number, the coordinates, and the pressure of the touch input applied to the first and second pressure sensors 2300 and 2400 may be determined by using the detection signal. The detection signal which serves as a base for the calculation unit 2540 to determine the touch input may be the data in which changes in power output from the piezoelectric layer 300 are digitized, and in particular, the data which indicates the difference in power between the case in which a touch has not occurred and the case in which touch has occurred.

As such, touch inputs to the first and second pressure sensors 2300 and 2400 may be determined by using the control unit 2500, and this may be transmitted to, for example, a main control unit of a host 4000 of an electronic device or the like. That is, the control unit 2500 generates X- and Y-coordinate data and Z-pressure data using the signal input from the pressure sensors 2300 and 2400 by using the detection unit 2520, the conversion unit 2530, the calculation unit 2540, etc. The X- and Y-coordinate data and Z-pressure data, which are generated as such, are transmitted to the host 4000, and the host 4000 detects, using, for example, a main controller, the touch and the pressure of the corresponding portion using the X- and Y-coordinate data and Z-pressure data.

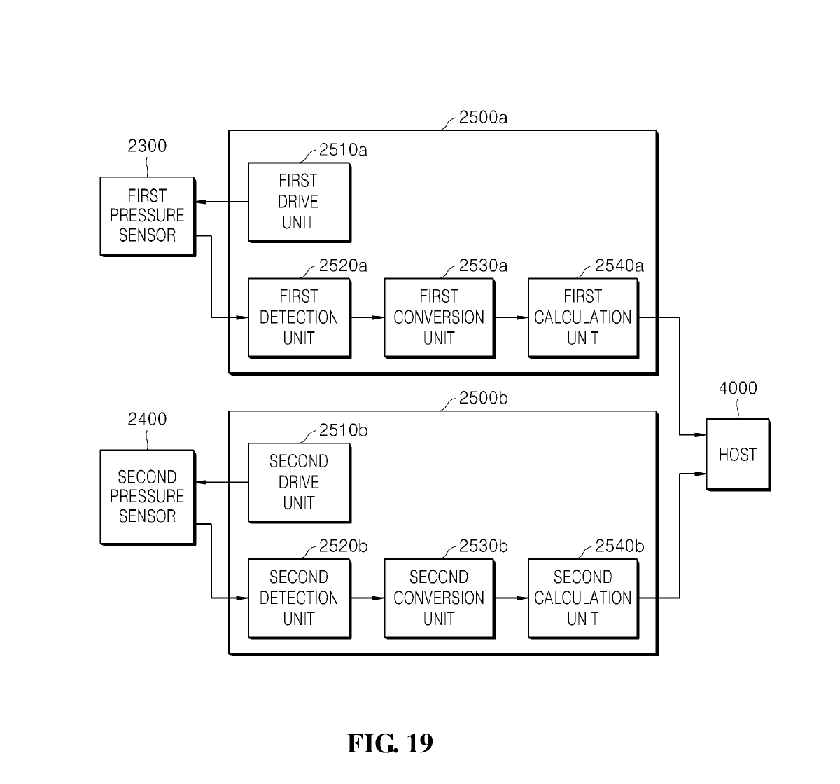

In addition, the control unit 2500 may include: a first control unit 2500a which processes the output of the first pressure sensor 2300; and a second control unit 2500b which processes the output of the second pressure sensor 2400. That is, FIG. 18 illustrates a single control unit 2500 which processes the outputs from the first and second pressure sensors 2300 and 2400, but as illustrated in FIG. 19, the control unit 2500 may include first and second control units 2500a and 2500b which respectively process the outputs of the first and second pressure sensors 2300 and 2400. Here, the first control unit 2500a may include a first drive part 2510a, a first detection unit 2520a, a first conversion unit 2530a and a first calculation unit 2540a, and the second control unit 2500a may include a second drive part 2510b, a second detection unit 2520b, a second conversion unit 2530b and a second calculation unit 2540b. Meanwhile, the first and second control units 2500a and 2500b may be implemented in integrated circuits (IC) different from each other. Accordingly, in order to process the outputs from the first and second pressure sensors 2300 and 2400, two integrated circuits may be required. Meanwhile, the first and second control units 2500a and 2500b may be implemented in integrated circuits (IC) different from each other. Detailed description on the configurations and functions of these first and second control units 2500a and 2500b will not be provided because the outputs from the first and second pressure sensors 2300 and 2400 are respectively processed by the first and second control units, which is the same as described above using FIG. 18.

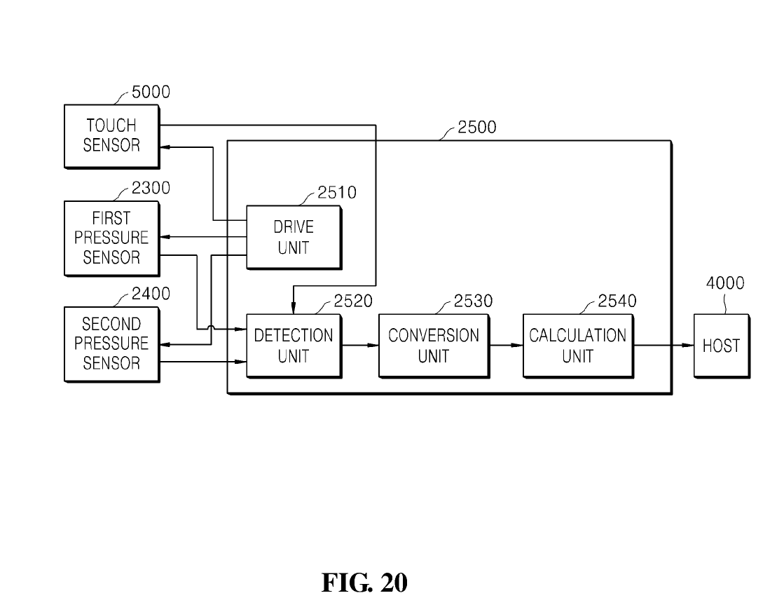

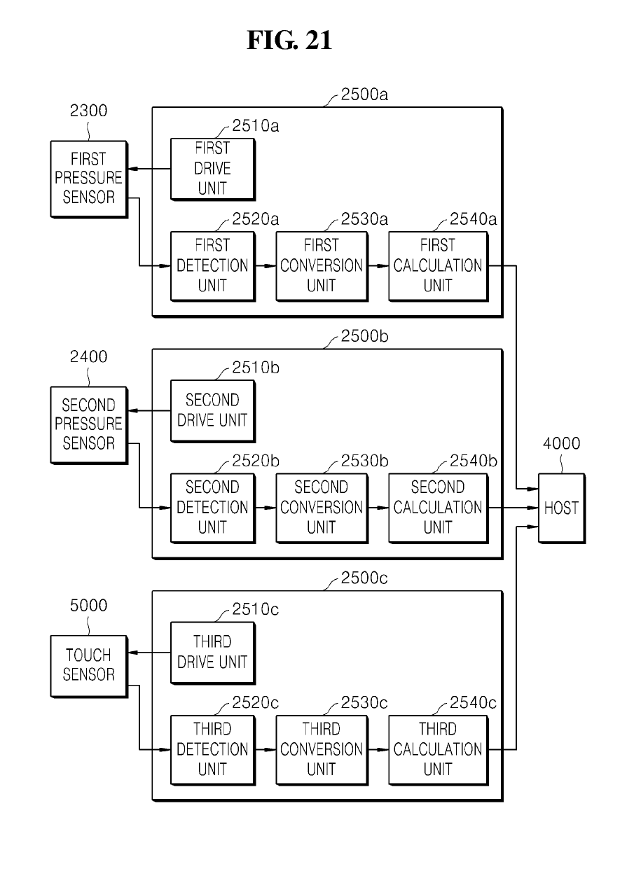

Meanwhile, the electronic device may also be further provided with a touch sensor besides at least one touch sensor of the first and second pressure sensors 2300 and 2400. In this case, the operation of the touch sensors may be performed by a single control unit 2500 as illustrated in FIG. 20. That is, the single control unit 2500 may control the at least one of the first and second pressure sensors 2300 and 2400 and the single touch sensor 5000. In addition, when the touch sensor 5000 is further provided, as illustrated in FIG. 21, besides the first and second control units 2500a and 2500b for controlling the first and second pressure sensors 2300 and 2400, a third control unit 2500c may further be provided. That is, in order to respectively control the first and second pressure sensors 2300 and 2400 and the touch sensor 5000, the plurality of control units may be provided.

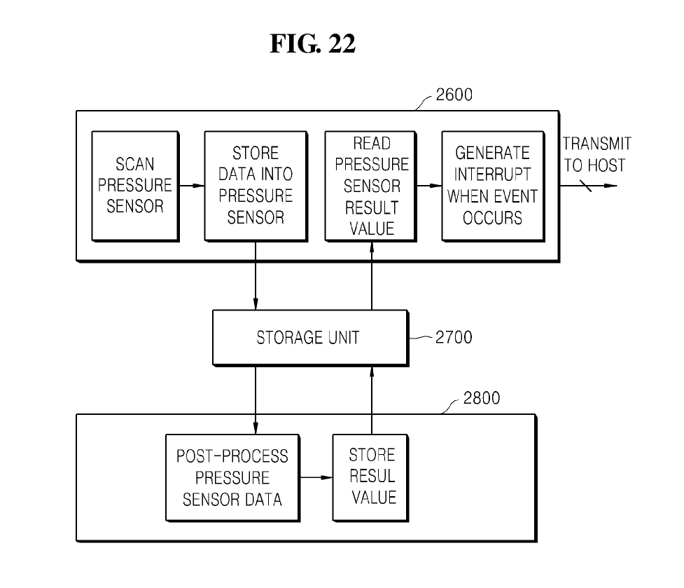

FIG. 22 is a bock diagram for describing a data processing method of a pressure sensor in accordance with another exemplary embodiment.

As illustrated in FIG. 22, in order to process the data of a pressure sensor in accordance with another exemplary embodiment, a first control unit 2600, a storage unit 2700, and a second control unit 2800 may be provided. Such a configuration may be implemented on the same IC, or also be implemented on different ICs. In addition, the data processing of the exemplary embodiment may be performed by cooperation of the first control unit 2600 and the second control unit 2800. Here, the first and second control units 2600 and 2800 may be provided to process the data of respective pressure sensors. In addition, any one (for example, the first control unit) of the first and second control units 2600 and 2800 may be the control unit for controlling a touch sensor and the other one (for example, the second control unit) may be the control unit for controlling the pressure sensors. In this case, the control unit for controlling the touch sensor may simultaneously control the touch sensor and the pressure sensor. In addition, the storage unit 2700 serves as a data transmission path of the first control unit 2600 and the second control unit 2800 and functions to store the data of the first and second control parts 2600 and 2800.

As illustrated in FIG. 22, the first control unit 2600 scans the pressure sensors and stores the raw data of the pressure sensors into the storage unit 2700. The second control part 2800 receives data from the storage unit 2700, processes the pressure sensor data, and stores the result values into the storage unit 2700. The result values stored into the storage unit 2700 may include data such as Z-axis, status, etc. The first control unit 2600 reads the result value of the pressure sensor from the storage unit 2700, and then generates and transmits, to a host, an interrupt when an event occurs.

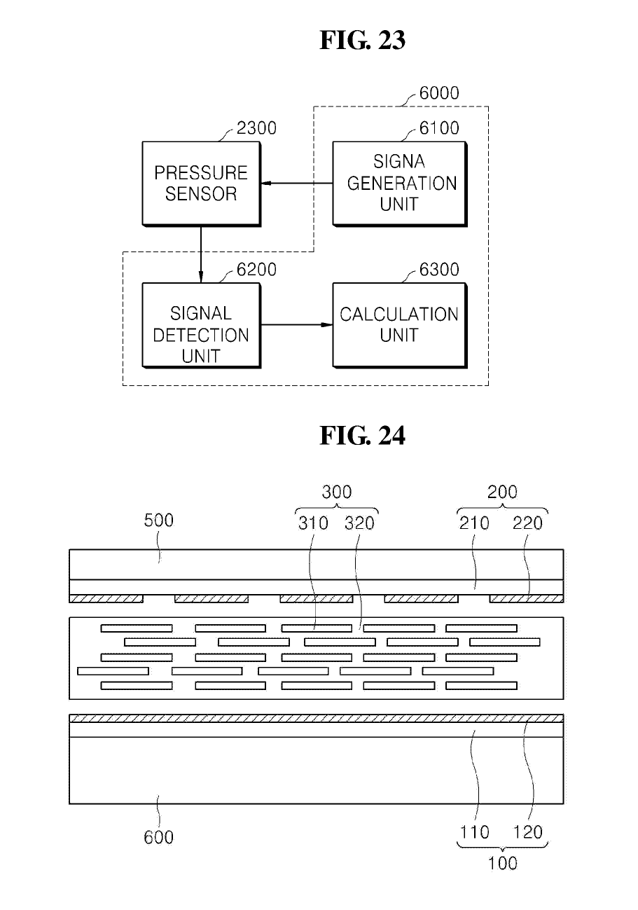

Meanwhile, as described above using FIGS. 11 to 13, the front surface input part 1360 of the electronic device 1000 may be configured from a fingerprint recognition sensor, and a pressure sensor in accordance with an exemplary embodiment may be used for the fingerprint recognition sensor. FIG. 23 is a configuration diagram of a fingerprint recognition sensor employing a pressure sensor in accordance with exemplary embodiments. In addition, FIG. 24 is a cross-sectional view of a pressure sensor in accordance with a second exemplary embodiment.

Referring to FIG. 23, a fingerprint recognition sensor employing a pressure sensor in accordance with an exemplary embodiment may include: a pressure sensor 2300; and a fingerprint detection unit 6000 which is electrically connected to the pressure sensor 2300 and detects a fingerprint. In addition, the fingerprint detection unit 6000 may include a signal generation unit 6100, a signal detection unit 6200, a calculation unit 6300, and the like.

Meanwhile, as illustrated in FIG. 24, the pressure sensor 2300 may further be provided with a protective layer 500 as a protective coating for the surface on which a finger is placed. The protective layer 500 may be manufactured by using urethane or another plastic which can function as a protective coating. The protective layer 500 is adhered to a second electrode layer 200 by using an adhesive. In addition, the pressure sensor 2300 may further include a support layer 600 which can be used as a support inside the pressure sensor 2300. The support layer 600 may be manufactured by using teflon or the like. Of course, instead of teflon, another type of supporting materials may be used for the support layer 600. The support layer 600 is adhered to a first electrode layer 100 by using an adhesive. Meanwhile, as illustrated in FIG. 4, the pressure sensor 2300 of an exemplary embodiment may be provided with the piezoelectric layer 300 divided into unit cells spaced predetermined distances apart from each other in one direction and another directions by the cutaway portions 330, and as illustrated in FIG. 7, the elastic layer 400 may be formed on the cutaway portion 330. In this case, it is desirable that the formed elastic layer 400 prevent respective vibrations from affecting each other.

The fingerprint detection unit 6000 may be connected to each of the first and second electrodes 110 and 210 which are provided on and under the piezoelectric layer 300 of the pressure sensor 2300. The fingerprint detection unit 6000 may generate an ultrasonic signal by vertically vibrating the piezoelectric layer 300 by applying, to the first and second electrodes 110 and 210, a voltage having a resonant frequency of an ultrasonic band.

The signal generation unit 6100 is electrically connected to the plurality of first and second electrodes 110 and 210 which are included in the pressure sensor 2300, and applies, to each electrode, an alternating current voltage having a predetermined frequency. While the piezoelectric layer 300 of the pressure sensor 2300 is vertically vibrated by the alternating current voltage applied to the electrodes, an ultrasonic signal having a predetermined resonant frequency, such as 10 MHz, is emitted to the outside.

A specific object may contact one surface on the pressure sensor 2300, for example, one surface of the protective layer 500. When the object contacting the one surface of the protective layer 500 is a human finger including a fingerprint, the reflective pattern of the ultrasonic signal emitted by the pressure sensor 2300 is differently determined according to the fine valleys and ridges which are present in the fingerprint. Assuming a case in which no object contacts a contact surface such as the one surface of the protective layer 500, most of the ultrasonic signal generated from the pressure sensor 2300 due to the difference in media between the contact surface and air cannot pass through the contact surface but is reflected and returned. On the contrary, when a specific object including a fingerprint contacts the contact surface, a portion of the ultrasonic signal which is generated from the pressure sensor 2300 directly contacting the ridges of the fingerprint passes through the interface between the contact surface and the fingerprint, and only a portion of the generated ultrasonic signal is reflected and returned. As such, the strength of the reflected and returned ultrasonic signal may be determined according to the acoustic impedance of each material. Consequently, the signal detection unit 6200 measures, from the pressure sensor 2300, the difference in the acoustic impedance generated by the ultrasonic signal at the valleys and ridges of the fingerprint, and may determine whether the corresponding region is the sensor in contact with the ridges of the fingerprint.

The calculation unit 6300 analyzes the signal detected by the signal detection unit 6200 and calculates the fingerprint pattern. The pressure sensor 2300 in which a low-strength reflected signal is generated is the pressure sensor 2300 contacting the ridges of the fingerprint, and the pressure sensor 2300 in which a high-strength signal is generated—ideally, the same strength as the strength of the output ultrasonic signal—is the pressure sensor 2300 corresponding to the valleys of the fingerprint. Accordingly, the fingerprint pattern may be calculated from the difference in the acoustic impedance detected from each region of the pressure sensor 2300.

The present invention may, however, be embodied in different forms and should not be construed as limited to the embodiments set forth herein. That is, the above embodiments are provided so that this invention will be thorough and complete, and will fully convey the scope of the present invention to those skilled in the art, and the scope of the present invention should be understood by the scopes of claims of the present application.

1. An electronic device comprising:
a window;
a display part configured to display an image through the window; and
a pressure sensor configured to detect a position and a pressure of a touch input applied through the window,
wherein the pressure sensor comprises:
first and second electrode layers provided spaced apart from each other; and
a piezoelectric layer provided between the first and second electrode layers,
and the piezoelectric layer comprises a plurality of plate-like piezoelectric bodies provided in a polymer.

2. The electronic device of claim 1, wherein the piezoelectric bodies are arranged in plurality in one direction and another direction crossing each other in a horizontal direction and are arranged in plurality in a vertical direction.

3. The electronic device of claim 1, wherein the piezoelectric bodies are provided to have densities of 30% to 99%.

4. The electronic device of claim 1, wherein the piezoelectric bodies comprise single crystals.

5. The electronic device of claim 1, wherein the piezoelectric bodies each comprise: a seed composition composed of:
an orientation raw material composition composed of a piezoelectric material having a perovskite crystalline structure; and
an oxide which is distributed in the orientation raw material composition and has a general formula ABO₃ (A is a bivalent metal element, and B is a tetravalent metal element).

6. An electronic device comprising:
a window;
a display part configured to display an image through the window; and
a pressure sensor configured to detect a position and a pressure of a touch input applied through the window,
wherein the pressure sensor comprises:
first and second electrode layers provided spaced apart from each other; and
a piezoelectric layer provided between the first and second electrode layers, and
the piezoelectric layer comprises a plurality of cutaway portions formed with predetermined widths and depths.

7. The electronic device of claim 6, wherein the cutaway portions are formed to depths of 50% to 100% of a thickness of the piezoelectric layer.

8. The electronic device of claim 6 further comprising an elastic layer provided inside the cutaway portions.

9. The electronic device of claim 6, wherein the piezoelectric layer comprises single crystals.

10. The electronic device of claim 6, wherein the piezoelectric bodies each comprise:
a seed composition comprising: an orientation raw material composition comprising a piezoelectric material having a perovskite crystalline structure; and
an oxide which is distributed in the orientation raw material composition and has a general formula ABO₃ (A is a bivalent metal element, and B is a tetravalent metal element).

11. The electronic device of claim 1, wherein the pressure sensor comprises at least any one of at least one first pressure sensor provided under the display part and at least one second pressure sensor provided under the window.

12. The electronic device of claim 11 further comprising a touch sensor provided between the window and the display part.

13. The electronic device of claim 11 further comprising an insulating layer provided on at least one among places on the first electrode layer, between the first and second electrode layers, and under the second electrode layer.

14. The electronic device of claim 11 further comprising first and second connection patterns respectively provided on the first and second electrode layers and connected to each other.
